(19) United States
(12) Patent Application Publication
(10) Pub. No.: US 2025/0359189 A1
(43) Pub. Date: Nov. 20, 2025

(54) FLASH MEMORY INCLUDING A COMPOSITE TUNNELING DIELECTRIC AND METHOD FOR FORMING THE SAME

(71) Applicant: Taiwan Semiconductor Manufacturing Company Limited, Hsinchu (TW)

(72) Inventors: Gerben Doornbos, Kessel-Lo (BE); Georgios Vellianitis, Heverlee (BE); Marcus Johannes Henricus Van Dal, Linden (BE)

(21) Appl. No.: 18/664,046

(22) Filed: May 14, 2024

(51) Int. Cl. H01L 29/423; H01L 23/522; H01L 23/528; H10B 41/10; H10B 41/27

(52) U.S. Cl. CPC H10D 30/6891; H01L 23/5226; H01L 23/5283; H10B 41/10; H10B 41/27

(57) ABSTRACT

A memory device may be provided by forming a composite tunneling dielectric including a first dielectric layer and a second dielectric layer over a control gate electrode. The first dielectric layer has a first conduction band offset relative to a Fermi energy of a conductive material in the control gate electrode. The second dielectric layer has a second conduction band offset relative to the Fermi energy of the conductive material. The first conduction band offset is greater than the second conduction band offset. A floating gate electrode is formed over the composite tunneling dielectric. A stack of a blocking dielectric and an active layer including a semiconductor material is formed over the floating gate electrode.

### BACKGROUND

A flash memory device comprises a control gate electrode and a floating gate electrode. A tunneling dielectric in the flash memory device is desired to provide efficient charge tunneling during programming while suppressing charge tunneling during a hold state. In other words, the tunneling dielectric is desired to provide good charge retention between programming or read operations. This dual requirement presents a notable challenge, as efficient charge tunneling and effective charge retention are inherently contradictory objectives. Nonetheless, achieving both efficient tunneling during programming and effective charge retention are both desired for superior performance of a flash memory device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first embodiment structure after formation of complementary metal-oxide-semiconductor (CMOS) transistors, metal interconnect structures and dielectric material layers, and an insulating layer according to an embodiment of the present disclosure.

FIGS. 2A and 2B are plan and vertical cross-sectional views of a first configuration of the first embodiment structure after formation of a control gate electrode material layer and a composite tunneling dielectric layer according to an embodiment of the present disclosure. FIG. 2B is a top-down view. FIG. 2A is a vertical cross-sectional view along the vertical plane A-A′ of FIG. 2B.

FIG. 3A is a magnified vertical cross-sectional view of the first embodiment structure of FIG. 2A in instances in which the composite tunneling dielectric layer is a first-type composite tunneling dielectric layer. FIG. 3B is a magnified vertical cross-sectional view of the first embodiment structure of FIG. 2A in instances in which the composite tunneling dielectric layer is a second-type composite tunneling dielectric layer. FIG. 3C is a magnified vertical cross-sectional view of the first embodiment structure of FIG. 2A in instances in which the composite tunneling dielectric layer is a third-type composite tunneling dielectric layer.

FIGS. 4A and 4B are plan and vertical cross-sectional views of the first configuration of the first embodiment structure after formation of a control gate electrode and a composite tunneling dielectric according to an embodiment of the present disclosure. FIG. 4B is a top-down view. FIG. 4A is a vertical cross-sectional view along the vertical plane A-A′ of FIG. 4B.

FIGS. 5A and 5B are plan and vertical cross-sectional views of a second configuration of the first embodiment structure after formation of a control gate electrode material layer and a composite tunneling dielectric layer according to an embodiment of the present disclosure. FIG. 5B is a top-down view. FIG. 5A is a vertical cross-sectional view along the vertical plane A-A′ of FIG. 5B.

FIGS. 6A and 6B are plan and vertical cross-sectional views of the second configuration of the first embodiment structure after formation of a control gate electrode and a composite tunneling dielectric according to an embodiment of the present disclosure. FIG. 6B is a top-down view. FIG. 6A is a vertical cross-sectional view along the vertical plane A-A′ of FIG. 6B.

FIGS. 7A and 7B are plan and vertical cross-sectional views of a third configuration of the first embodiment structure prior to bonding a first wafer including a metallic control gate electrode material layer and a second wafer including a semiconductor control gate material layer and a composite tunneling dielectric layer according to an embodiment of the present disclosure. FIG. 7B is a top-down view. FIG. 7A is a vertical cross-sectional view along the vertical plane A-A′ of FIG. 7B.

FIGS. 8A and 8B are plan and vertical cross-sectional views of the third configuration of the first embodiment structure after bonding the first wafer and the second wafer according to an embodiment of the present disclosure. FIG. 8B is a top-down view. FIG. 8A is a vertical cross-sectional view along the vertical plane A-A′ of FIG. 8B.

FIGS. 9A and 9B are plan and vertical cross-sectional views of the third configuration of the first embodiment structure after removal of the carrier substrate from the second wafer according to an embodiment of the present disclosure. FIG. 9B is a top-down view. FIG. 9A is a vertical cross-sectional view along the vertical plane A-A′ of FIG. 9B.

FIGS. 10A and 10B are plan and vertical cross-sectional views of the third configuration of the first embodiment structure after formation of a control gate electrode and a composite tunneling dielectric according to an embodiment of the present disclosure. FIG. 10B is a top-down view. FIG. 10A is a vertical cross-sectional view along the vertical plane A-A′ of FIG. 10B.

FIGS. 11A and 11B are plan and vertical cross-sectional views of the first embodiment structure after formation of a control gate electrode and a composite tunneling dielectric according to an embodiment of the present disclosure. FIG. 11B is a top-down view. FIG. 11A is a vertical cross-sectional view along the vertical plane A-A′ of FIG. 11B.

FIGS. 12A and 12B are plan and vertical cross-sectional views of the first embodiment structure after formation of a dielectric matrix layer according to an embodiment of the present disclosure. FIG. 12B is a top-down view. FIG. 12A is a vertical cross-sectional view along the vertical plane A-A′ of FIG. 12B.

FIGS. 13A and 13B are plan and vertical cross-sectional views of the first embodiment structure after formation of a floating gate electrode material layer, a blocking dielectric layer, and a semiconductor layer according to an embodiment of the present disclosure. FIG. 13B is a top-down view. FIG. 13A is a vertical cross-sectional view along the vertical plane A-A′ of FIG. 13B.

FIGS. 14A and 14B are plan and vertical cross-sectional views of the first embodiment structure after formation of a floating gate electrode, a blocking dielectric, and an active layer according to an embodiment of the present disclosure. FIG. 14B is a top-down view. FIG. 14A is a vertical cross-sectional view along the vertical plane A-A′ of FIG. 14B.

FIGS. 15A and 15B are plan and vertical cross-sectional views of the first embodiment structure after formation of a contact-level dielectric layer according to an embodiment of the present disclosure. FIG. 15B is a top-down view. FIG. 15A is a vertical cross-sectional view along the vertical plane A-A′ of FIG. 15B.

FIGS. 16A and 16B are plan and vertical cross-sectional views of the first embodiment structure after formation of a source contact via cavity and a drain contact via cavity according to an embodiment of the present disclosure. FIG. 16B is a top-down view. FIG. 16A is a vertical cross-sectional view along the vertical plane A-A′ of FIG. 16B.

FIGS. 17A and 17B are plan and vertical cross-sectional views of the first embodiment structure after formation of a source contact structure and a drain contact structure according to an embodiment of the present disclosure. FIG. 17B is a top-down view. FIG. 17A is a vertical cross-sectional view along the vertical plane A-A′ of FIG. 17B.

FIGS. 18A and 18B are plan and vertical cross-sectional views of the first embodiment structure after formation of a line-level dielectric layer, a source line, and a drain line according to an embodiment of the present disclosure. FIG. 18B is a top-down view. FIG. 18A is a vertical cross-sectional view along the vertical plane A-A′ of FIG. 18B.

FIGS. 19A and 19B are plan and vertical cross-sectional views of an alternative configuration of the first embodiment structure after formation of a line-level dielectric layer, a source line, and a drain line according to an embodiment of the present disclosure. FIG. 19B is a top-down view. FIG. 19A is a vertical cross-sectional view along the vertical plane A-A′ of FIG. 19B.

FIGS. 20A and 20B are plan and vertical cross-sectional views of a first configuration of a second embodiment structure after formation of a control gate electrode material layer, a composite tunneling dielectric layer, and a first floating gate electrode material layer according to an embodiment of the present disclosure. FIG. 20B is a top-down view. FIG. 20A is a vertical cross-sectional view along the vertical plane A-A′ of FIG. 20B.

FIGS. 21A and 21B are plan and vertical cross-sectional views of the first configuration of the second embodiment structure after formation of a control gate electrode, a composite tunneling dielectric, and a first floating gate electrode portion according to an embodiment of the present disclosure. FIG. 21B is a top-down view. FIG. 21A is a vertical cross-sectional view along the vertical plane A-A′ of FIG. 21B.

FIGS. 22A and 22B are plan and vertical cross-sectional views of a second configuration of the second embodiment structure after formation of a control gate electrode material layer, a composite tunneling dielectric layer, and a first floating gate electrode material layer according to an embodiment of the present disclosure. FIG. 22B is a top-down view. FIG. 22A is a vertical cross-sectional view along the vertical plane A-A′ of FIG. 22B.

FIGS. 23A and 23B are plan and vertical cross-sectional views of the second configuration of the second embodiment structure after formation of a control gate electrode, a composite tunneling dielectric, and a first floating gate electrode portion according to an embodiment of the present disclosure. FIG. 23B is a top-down view. FIG. 23A is a vertical cross-sectional view along the vertical plane A-A′ of FIG. 23B.

FIGS. 24A and 24B are plan and vertical cross-sectional views of the second embodiment structure after formation of a dielectric matrix layer according to an embodiment of the present disclosure. FIG. 24B is a top-down view. FIG. 24A is a vertical cross-sectional view along the vertical plane A-A′ of FIG. 24B.

FIGS. 25A and 25B are plan and vertical cross-sectional views of the second embodiment structure after formation of a source contact structure and a drain contact structure according to an embodiment of the present disclosure. FIG. 25B is a top-down view. FIG. 25A is a vertical cross-sectional view along the vertical plane A-A′ of FIG. 25B.

FIGS. 26A and 26B are various views of the second embodiment structure after formation of a line-level dielectric layer, a source line, and a drain line according to an embodiment of the present disclosure. FIG. 26B is a top-down view. FIG. 26A is a vertical cross-sectional view along the vertical plane A-A′ of FIG. 26B.

FIGS. 27A and 27B are plan and vertical cross-sectional views of a third embodiment structure after formation of a lower dielectric matrix layer and a gate cavity according to an embodiment of the present disclosure. FIG. 27B is a top-down view. FIG. 27A is a vertical cross-sectional view along the vertical plane A-A′ of FIG. 27B.

FIGS. 28A and 28B are plan and vertical cross-sectional views of the third embodiment structure after formation of a control gate electrode according to an embodiment of the present disclosure. FIG. 28B is a top-down view. FIG. 28A is a vertical cross-sectional view along the vertical plane A-A′ of FIG. 28B.

FIGS. 29A and 29B are plan and vertical cross-sectional views of the third embodiment structure after formation of a composite tunneling dielectric layer according to an embodiment of the present disclosure. FIG. 29B is a top-down view. FIG. 29A is a vertical cross-sectional view along the vertical plane A-A′ of FIG. 29B.

FIGS. 30A and 30B are plan and vertical cross-sectional views of the third embodiment structure after patterning the composite tunneling dielectric layer into a composite tunneling dielectric according to an embodiment of the present disclosure.

FIG. 30B is a top-down view. FIG. 30A is a vertical cross-sectional view along the vertical plane A-A′ of FIG. 30B.

FIGS. 31A and 31B are plan and vertical cross-sectional views of the third embodiment structure after formation of an upper dielectric matrix layer, a floating gate electrode, a blocking dielectric, and an active layer according to an embodiment of the present disclosure. FIG. 31B is a top-down view. FIG. 31A is a vertical cross-sectional view along the vertical plane A-A′ of FIG. 31B.

FIGS. 32A and 32B are plan and vertical cross-sectional views of the third embodiment structure after formation of a contact-level dielectric layer, a source contact structure, a drain contact structure, a line-level dielectric layer, a source line, and a drain line according to an embodiment of the present disclosure. FIG. 32B is a top-down view. FIG. 32A is a vertical cross-sectional view along the vertical plane A-A′ of FIG. 32B.

FIGS. 33A and 33B are plan and vertical cross-sectional views of a first alternative configuration of the third embodiment structure after formation of a composite tunneling dielectric layer according to an embodiment of the present disclosure. FIG. 33B is a top-down view. FIG. 33A is a vertical cross-sectional view along the vertical plane A-A′ of FIG. 33B.

FIGS. 34A and 34B are plan and vertical cross-sectional views of a first alternative configuration of the third embodiment structure after formation of a contact-level dielectric layer, a source contact structure, a drain contact structure, a line-level dielectric layer, a source line, and a drain line according to an embodiment of the present disclosure. FIG. 34B is a top-down view. FIG. 34A is a vertical cross-sectional view along the vertical plane A-A′ of FIG. 34B.

FIGS. 35A and 35B are plan and vertical cross-sectional views of a second alternative configuration of the third embodiment structure after formation of a contact-level dielectric layer, a source contact structure, a drain contact structure, a line-level dielectric layer, a source line, and a drain line according to an embodiment of the present disclosure. FIG. 35B is a top-down view. FIG. 35A is a vertical cross-sectional view along the vertical plane A-A′ of FIG. 35B.

FIGS. 36A and 36B are plan and vertical cross-sectional views of a fourth embodiment structure after formation of stacks of a floating gate electrode, a blocking dielectric, and an active layer according to an embodiment of the present disclosure.

FIG. 36B is a top-down view. FIG. 36A is a vertical cross-sectional view along the vertical plane A-A′ of FIG. 36B.

FIGS. 37A and 37B are plan and vertical cross-sectional views of the fourth embodiment structure after formation of a contact-level dielectric layer, source contact via cavities, and a drain contact via cavities according to an embodiment of the present disclosure. FIG. 37B is a top-down view. FIG. 37A is a vertical cross-sectional view along the vertical plane A-A′ of FIG. 37B.

FIGS. 38A and 38B are plan and vertical cross-sectional views of the fourth embodiment structure after formation of source contact structures and drain contact structures according to an embodiment of the present disclosure. FIG. 38B is a top-down view. FIG. 38A is a vertical cross-sectional view along the vertical plane A-A′ of FIG. 38B.

FIGS. 39A-39C are plan and vertical cross-sectional views of the fourth embodiment structure after formation of a via-level dielectric layer and connection via structures according to an embodiment of the present disclosure. FIG. 39B is a top-down view. FIG. 39A is a vertical cross-sectional view along the vertical plane A-A′ of FIG. 39B. FIG. 39C is a vertical cross-sectional view along the vertical plane C-C′ of FIG. 39C.

FIGS. 40A-40C are vertical cross-sectional views of the fourth embodiment structure after formation of a line-level dielectric layer, a source line, and a drain line according to an embodiment of the present disclosure. FIG. 40B is a top-down view. FIG. 40A is a vertical cross-sectional view along the vertical plane A-A′ of FIG. 40B. FIG. 40C is a vertical cross-sectional view along the vertical plane C-C′ of FIG. 40B.

FIG. 41 is a schematic top-down view of selected structural elements within an alternative configuration of the fourth embodiment structure.

FIGS. 42A and 42B are plan and vertical cross-sectional views of a fifth embodiment structure after formation of floating gate electrodes according to an embodiment of the present disclosure. FIG. 42B is a top-down view. FIG. 42A is a vertical cross-sectional view along the vertical plane A-A′ of FIG. 42B.

FIGS. 43A and 43B are plan and vertical cross-sectional views of a fifth embodiment structure after formation of a floating-gate-level dielectric layer, a blocking dielectric, and an active layer according to an embodiment of the present disclosure. FIG. 43B is a top-down view. FIG. 43A is a vertical cross-sectional view along the vertical plane A-A′ of FIG. 43B.

FIGS. 44A and 44B are plan and vertical cross-sectional views of the fifth embodiment structure after formation of a contact-level dielectric layer, source contact structures, and drain contact structures according to an embodiment of the present disclosure. FIG. 44B is a top-down view. FIG. 44A is a vertical cross-sectional view along the vertical plane A-A′ of FIG. 44B.

FIGS. 45A-45C are vertical cross-sectional views of the fifth embodiment structure after formation of a via-level dielectric layer, connection via structures, a line-level dielectric layer, a source line, and a drain line according to an embodiment of the present disclosure. FIG. 45B is a top-down view. FIG. 45A is a vertical cross-sectional view along the vertical plane A-A′ of FIG. 45B. FIG. 45C is a vertical cross-sectional view along the vertical plane C-C′ of FIG. 45B.

FIG. 46 is a vertical cross-sectional view of an embodiment structure after formation of arrays of memory cells, upper-level dielectric material layers, and upper-level metal interconnect structures according to an embodiment of the present disclosure.

FIG. 47A is a band gap diagram of a region including a floating gate electrode, a tunneling dielectric, and a control gate electrode during programming of a memory cell of the present disclosure.

FIG. 47B is a band gap diagram of a region including a floating gate electrode, a tunneling dielectric, and a control gate electrode during a charge hold condition of a memory cell of the present disclosure.

FIG. 48 illustrates the shift in the programming voltage-retention time characteristics that may be achieved by the composite tunneling dielectric of the present disclosure.

FIG. 49 illustrates a conduction band offset of various dielectric materials relative to a conduction edge of titanium nitride.

FIG. 50 is a first flowchart that illustrates general processing steps for manufacturing a device structure according to embodiments of the present disclosure.

FIG. 51 is a second flowchart that illustrates general processing steps for manufacturing a device structure according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device structure may be rotated as needed, and the spatially relative descriptors used herein may likewise be interpreted accordingly. Elements with the same reference numerals refer to the same element, and are presumed to have the same material composition and the same thickness range unless expressly indicated otherwise.

The present disclosure is directed to the field of non-volatile memory (NVM) technologies, more specifically to embedded flash memory devices.

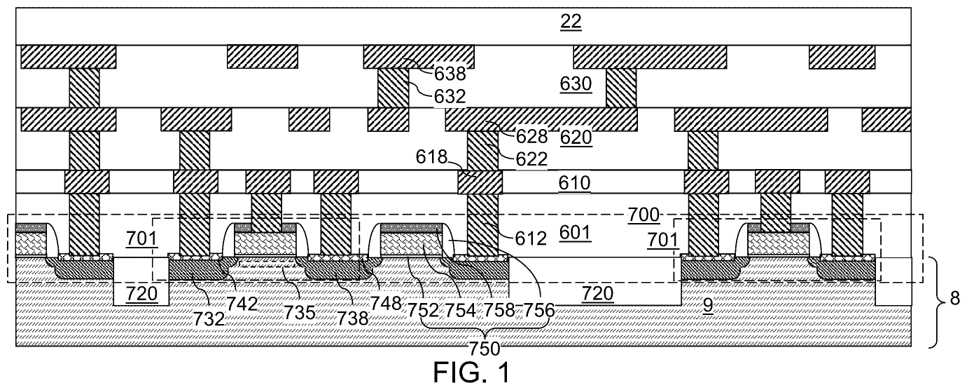

Referring to FIG. 1, a first embodiment structure according to an embodiment of the present disclosure is illustrated. The first embodiment structure includes a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source contact electrode 732, a drain contact electrode 738, a semiconductor channel 735 that includes a surface portion of the substrate 8 extending between the source contact electrode 732 and the drain contact electrode 738, and a gate structure 750. The semiconductor channel 735 may include a single crystalline semiconductor material. Each gate structure 750 may include a gate dielectric layer 752, a gate contact electrode 754, a gate cap dielectric 758, and a dielectric gate spacer 756. A source-side metal-semiconductor alloy region 742 may be formed on each source contact electrode 732, and a drain-side metal-semiconductor alloy region 748 may be formed on each drain contact electrode 738. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as CMOS circuitry 700.

One or more of the field effect transistors 701 in the CMOS circuitry 700 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel. In one embodiment, a subset of the field effect transistors 701 in the CMOS circuitry 700 may include a respective node that is subsequently electrically connected to a node of an energy harvesting device and/or to a battery structure to be subsequently formed. While the present disclosure is described using an embodiment in which the field effect transistors 701 have a configuration of a planar field effect transistor, the field effect transistors 701 may be formed in any configuration known for CMOS transistors. For example, the field effect transistors 701 may be formed as fin field effect transistors or gate-all-around (GAA) field effect transistors.

In one embodiment, the substrate 8 may include a single crystalline silicon substrate, and the field effect transistors 701 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

Various metal interconnect structures formed within dielectric material layers may be subsequently formed over the substrate 8 and the semiconductor devices thereupon (such as field effect transistors 701). In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, and a third interconnect-level dielectric material layer 630. The metal interconnect structures may include device contact via structures 612 formed in the first dielectric material layer 601 and contact a respective component of the CMOS circuitry 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, and third metal line structures 638 formed in an upper portion of the third interconnect-level dielectric material layer 630. While the present disclosure is described using an embodiment in which three levels of metal line structures are formed in dielectric material layers, embodiments are expressly contemplated herein in which a lesser or greater number of levels of metal line structures are formed in dielectric material layers.

Each of the dielectric material layers (601, 610, 620, 630) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. Generally, any contiguous set of a metal line structure (628, 638) and at least one underlying metal via structure (622, 632) may be formed as an integrated line and via structure.

Generally, semiconductor devices may be formed on a substrate 8, and metal interconnect structures (612, 618, 622, 628, 632, 638) and dielectric material layers (601, 610, 620, 630) over the semiconductor devices. The metal interconnect structures (612, 618, 622, 628, 632, 638) may be formed in the dielectric material layers (601, 610, 620, 630, 640), and may be electrically connected to the semiconductor devices. The metal interconnect structures (612, 618, 622, 628, 632, 638) are herein referred to as lower interconnect-level metal interconnect structures. The dielectric material layers (601, 610, 620, 630) are herein referred to as lower interconnect-level dielectric material layers.

An insulating layer 22 may be deposited over the metal interconnect structures (612, 618, 622, 628, 632, 638) and dielectric material layers (601, 610, 620, 630). The insulating layer 22 includes an insulating material such as silicon oxide, silicon carbide, silicon nitride, or silicon carbide nitride. Other suitable dielectric capping materials are within the contemplated scope of disclosure. The thickness of the insulating layer 22 may be in a range from 10 nm to 200 nm, although lesser and greater thicknesses may also be used.

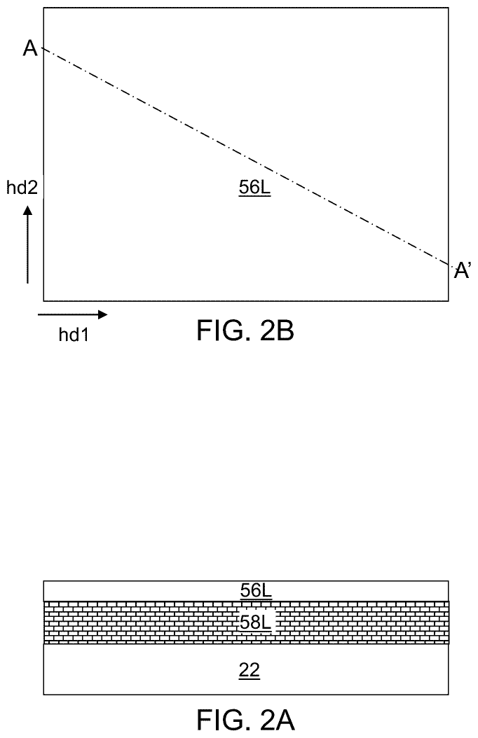

Referring to FIGS. 2A and 2B, a first configuration of the first embodiment structure is illustrated after formation of a control gate electrode material layer 58L and a composite tunneling dielectric layer 56L. The control gate electrode material layer 58L comprises a conductive material such as a metallic material. For example, the control gate electrode material layer 58L may comprise, and/or may consist essentially of, titanium nitride, tungsten, copper, ruthenium, cobalt, or highly-doped silicon. The control gate electrode material layer 58L may be formed by atomic layer deposition (ALD) physical vapor deposition (PVD) or chemical vapor deposition (CVD). The thickness of the control gate electrode material layer 58L may be in a range from 10 nm to 40 nm, although lesser and greater thicknesses may also be used. A first horizontal direction hd1 and a second horizontal direction hd2 that is perpendicular to the first horizontal direction hd1 are shown in FIG. 2B.

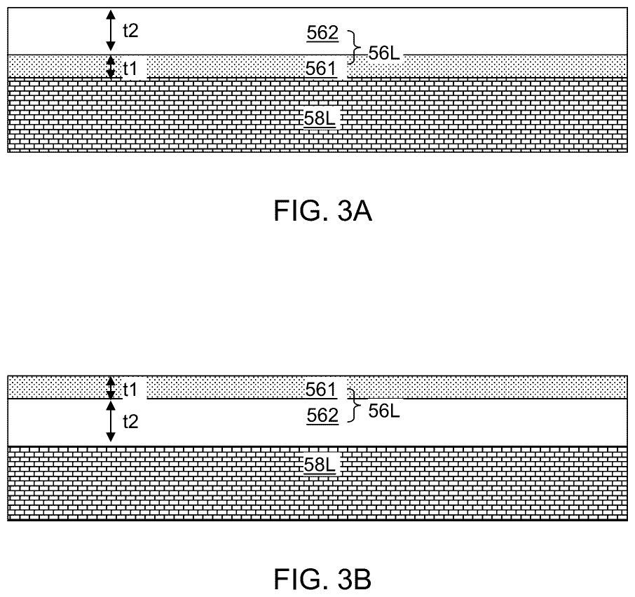

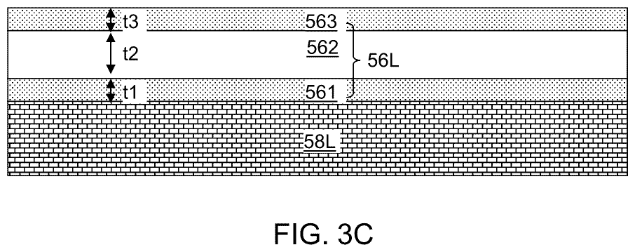

The composite tunneling dielectric layer 56L may be formed as a layer stack including at least a first dielectric layer 561 and a second dielectric layer 562 as illustrated in FIGS. 3A-3C. FIG. 3A is a magnified vertical cross-sectional view of the first embodiment structure of FIG. 2A in instances in which the composite tunneling dielectric layer 56L is a first-type composite tunneling dielectric layer 56L. FIG. 3B is a magnified vertical cross-sectional view of the first embodiment structure of FIG. 2A in instances in which the composite tunneling dielectric layer 56L is a second-type composite tunneling dielectric layer 56L. FIG. 3C is a magnified vertical cross-sectional view of the first embodiment structure of FIG. 2A in instances in which the composite tunneling dielectric layer 56L is a third-type composite tunneling dielectric layer 56L.

The composite tunneling dielectric layer 56L may consist of a layer stack including a first dielectric layer 561 and a second dielectric layer 562 as illustrated in FIGS. 3A and 3B. The first dielectric layer 561 may be formed directly on a top surface of the control gate electrode material layer 58L, and the second dielectric layer 562 may be formed on a top surface of the first dielectric layer 561 as illustrated in FIG. 3A. Alternatively, the second dielectric layer 562 may be formed directly on a top surface of the control gate electrode material layer 58L, and the first dielectric layer 561 may be formed on a top surface of the second dielectric layer 562 as illustrated in FIG. 3B.

Alternatively, the composite tunneling dielectric layer 56L may comprise a layer stack including, from bottom to top, a first dielectric layer 561, a second dielectric layer 562, and an additional third dielectric layer 563 as illustrated in FIG. 3C.

According to an aspect of the present disclosure, the first dielectric layer 561 has a first conduction band offset relative to a Fermi energy of a conductive material in the control gate electrode 58, and the second dielectric layer 562 has a second conduction band offset relative to a Fermi energy of the conductive material. The first conduction band offset is the difference in the energy level between the conduction band edge of the material of the first dielectric layer 561 relative to the Fermi energy of the material of the control gate electrode material layer 58L. The second conduction band offset is the difference in the energy level between the conduction band edge of the material of the second dielectric layer 562 relative to the Fermi energy of the material of the control gate electrode material layer 58L. Further, the material of the additional third dielectric layer 563, in instances where it is present, may have a third conduction band offset relative to the Fermi energy of the control gate electrode material layer 58L.

According to an aspect of the present disclosure, the first conduction band offset may be greater than the second conduction band offset. In one embodiment, the first conduction band offset is greater than the second conduction band offset by at least 2.00 eV. According to an aspect of the present disclosure, the material of the first dielectric layer 561 and the material of the second dielectric layer 562 are selected such that the first conduction band offset is greater than the second conduction band offset by at least 2.00 eV. In one embodiment, the first dielectric layer 561 and the second dielectric layer 561 are made of different dielectric metal containing compounds. In one embodiment, the first dielectric layer 561 comprises a material selected from AlN and Al₂O₃, and the second dielectric layer 562 comprises a material selected from Ta₂O₅, Ga₂O₃, Nb₂O₅, TiO₂, and SiTiO₃. In embodiments in which an additional third dielectric layer 563 is present, the third conduction band offset is greater than the second conduction band offset by at least 2.00 eV, and may comprise a material selected from AlN and Al₂O₃, The material of the third dielectric layer 563 may be the same as, or may be different from, the material of the first dielectric layer 561.

TABLE 1
conduction band edge offset of various materials
relative to the Fermi energy in titanium nitride

| | | |
|---|---|---|
| AlN | 4.0 | eV |
| Al₂O₃ | 3.5 | eV |
| Ta₂O₅ | 1.0 | eV |
| Ga₂O₃ | 1.25 | eV |
| Nb₂O₅ | 0.35 | eV |
| TiO₂ | 0.60 | eV |
| SiTiO₃ | 0.60 | eV |

Each of the first dielectric layer 561 and the second dielectric layer 562 may be deposited by a respective deposition process, which may be independently selected from chemical vapor deposition, physical vapor deposition, atomic layer deposition, or any other alternative deposition method. The first dielectric layer 561 has a first thickness t1, and the second dielectric layer 562 has a second thickness t2. In instance in which it is present, the additional third dielectric layer 563 has a third thickness t3. According to an aspect of the present disclosure, the second thickness t2 is greater than the first thickness t1. In embodiments in which the additional third dielectric layer 563 is present, the second thickness t2 is greater than the third thickness t3.

Generally, the total thickness (i.e., the sum of t1 and t2, and t3 in embodiments in which the additional third dielectric layer 563 is present) of the composite tunneling dielectric layer 56L may be in a range from 4 nm to 12 nm, and the first thickness t1, the second thickness t2, and the third thickness t3 (if applicable) are selected to optimize programming efficiency during operation of a floating gate memory device to be subsequently formed. In other words, the first thickness t1, the second thickness t2, and the third thickness t3 (if applicable) are selected to provide optimal charge tunneling during programming. In an illustrative example, the first thickness t1 may be in a range from 1 nm to 4 nm, and the second thickness t2 may be in a range from 2.5 nm to 7 nm. In embodiments in which the additional third dielectric layer 563 is present, the third thickness t3 may be in a range from 1 nm to 2.5 nm. For example, by increasing the total thickness of the composite tunneling dielectric layer 56L, a higher voltage may be demanded for programming. However, this may result in an improved charge retention. In contrast, by decreasing the total thickness of the composite tunneling dielectric layer 56L, a lower voltage may be demanded for programming. However, this may result in a degraded charge retention.

Optimization of the tunneling properties of the composite tunneling dielectric layer 56L can be effected through the adjustment of the thicknesses of the first dielectric layer 561 and the second dielectric layer 562 and the optional additional third dielectric layer 563. The total thickness of the composite tunneling dielectric layer 56L is a parameter that controls the retention capabilities. During the hold state, electrons must tunnel through the entirety of the composite tunneling dielectric layer 56L to induce the undesired data loss. The first dielectric layer 561 is engineered to provide a high energy barrier, that influences the write voltage. Under write conditions, the barrier effectively becomes triangular and renders the contribution of the second dielectric layer 562 to the overall energy barrier to become minimal, and the tunneling properties are predominantly determined by the first dielectric layer 561. In embodiments in which a write operation with a write voltage in a range from 1 V to 2 V is desired, the thickness of the first dielectric layer 561 may be in a range from 1 nm to 3 nm, such as about 2 nm. However, a thickness of 2 nm for the first dielectric layer 561 without any second dielectric layer 562 in the composite tunneling dielectric layer 56L would lead to suboptimal charge retention. Thus, the addition of the second dielectric layer 562 is desired to provide sufficient charge retention by the composite tunneling dielectric layer 56L. The thickness of the second dielectric layer 562 may be selected at a level that enhances retention without excessive increase in the programming voltage, thereby providing a lower energy barrier compared to the energy barrier provided by the first dielectric layer 561. The thickness of the second dielectric layer 562 may be in a range from 4 nm to 10 nm, such as 6 nm. The thicknesses of the first dielectric layer 561 and the second dielectric layer 562 and the optional additional third dielectric layer 563 may be selected to ensure that the flash memory device of the present disclosure meets the intricate requirements of efficient charge tunneling during programming and robust charge retention during the hold state.

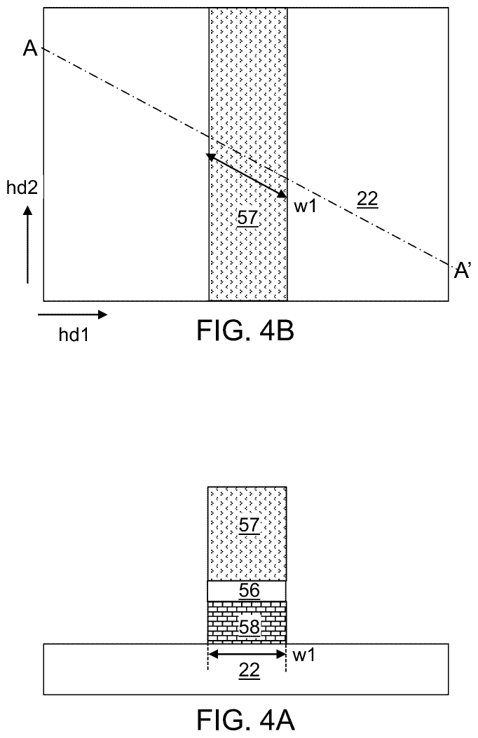

Referring to FIGS. 4A and 4B, a photoresist layer 57 may be applied over the composite tunneling dielectric layer 56L, and may be lithographically patterned in the pattern of word lines laterally extending along the second horizontal direction hd2 with a uniform width along the first horizontal direction hd1. The patterned portion of the photoresist layer 57 may have a line-and-space pattern having a periodicity along the first horizontal direction hd1 and laterally extending along the second horizontal direction hd2.

The area illustrated in FIG. 4B corresponds to the area of a unit memory cell to be subsequently formed. Thus, the length of the illustrated area long the first horizontal direction hd1 corresponds the length of a unit memory cell along the first horizontal direction hd1, and the width of the illustrated area long the second horizontal direction corresponds to the width of the unit memory cell along the second horizontal direction hd2. Accordingly, the length of the illustrated area long the first horizontal direction hd1 corresponds to the periodicity of a two-dimensional array of flash memory cells to be subsequently formed along the first horizontal direction hd1, and the width of the illustrated area long the second horizontal direction hd2 corresponds to the periodicity of the two-dimensional array of flash memory cells to be subsequently formed along the second horizontal direction hd2.

An anisotropic etch process may be performed to etch unmasked portions of the composite tunneling dielectric layer 56L and the control gate electrode material layer 58L, i.e., portions that are not masked by the patterned portions of the photoresist layer 57. Each remaining portion of the control gate electrode material layer 58L comprises a control gate electrode 58, and each remaining portion of the composite tunneling dielectric layer 56L comprises a composite tunneling dielectric 56. A stack of a composite tunneling dielectric 56 and a control gate electrode 58 is formed underneath each patterned portion of the photoresist layer 57. Each of the composite tunneling dielectric 56 and the control gate electrode 58 may have a uniform width along the first horizontal direction hd1, which is herein referred to as a first width w1. The first width w1 may be in a range from 20 nm to 120 nm, although lesser and greater widths may also be used. The photoresist layer 57 may be subsequently removed, for example, by ashing.

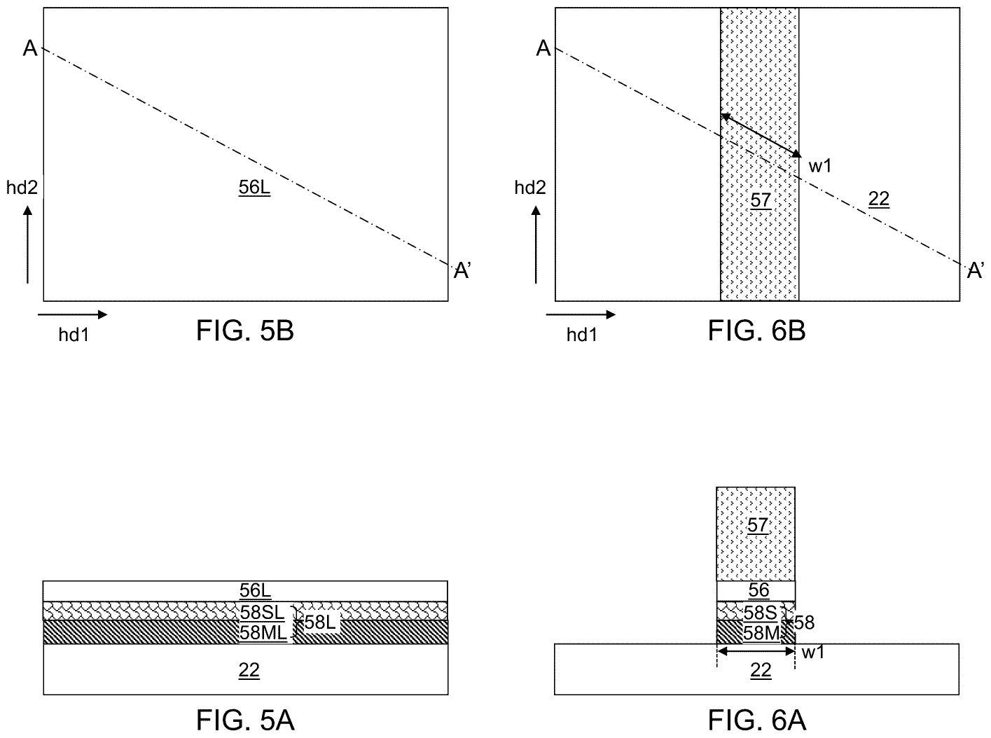

Referring to FIGS. 5A and 5B, a second configuration of the first embodiment structure is illustrated after formation of a control gate electrode material layer 58L and a composite tunneling dielectric layer 56L. The second configuration of the first embodiment structure may be derived from the first configuration of the first embodiment structure illustrated in FIGS. 2A and 2B by using a stack of a metallic control gate electrode material layer 58ML comprising a metallic material and a semiconductor control gate electrode material layer 58SL comprising a heavily doped semiconductor material. For example, the metallic control gate electrode material layer 58ML may comprise a material such as titanium nitride, tungsten, copper, ruthenium, cobalt, etc., and the semiconductor control gate electrode material layer 58SL may comprise a heavily doped semiconductor material such as heavily doped silicon. The thickness of the metallic control gate electrode material layer 58ML may be in a range from 5 nm to 20 nm, although lesser and greater thicknesses may also be used. The thickness of the semiconductor control gate electrode material layer 58SL may be in a range from 5 nm to 20 nm, although lesser and greater thicknesses may also be used.

The composite tunneling dielectric layer 56L may be the same as in the first configuration of the first embodiment structure described with reference to FIGS. 2A, 2B, and 3A-3C. Thus, the composite tunneling dielectric layer 56L in the second configuration of the first embodiment structure illustrated in FIGS. 5A and 5B may have any configuration described with reference to FIGS. 3A-3C. The conduction band offsets of each material within the composite tunneling dielectric layer 56L may be measured relative to the Fermi energy of the conductive material within the semiconductor control gate electrode material layer 58SL. As discussed above, the material of the first dielectric layer 561 and the material of the second dielectric layer 562 are selected such that the first conduction band offset is greater than the second conduction band offset by at least 2.00 eV. In one embodiment, the first dielectric layer 561 comprises a material selected from AlN and Al₂O₃, and the second dielectric layer 562 comprises a material selected from Ta₂O₅, Ga₂O₃, Nb₂O₅, TiO₂, and SiTiO₃. In embodiments in which an additional third dielectric layer 563 is present, the third conduction band offset relative is greater than the second conduction band offset by at least 2.00 eV, and may comprise a material selected from AlN and Al₂O₃, The material of the additional third dielectric layer 563 may be the same as, or may be different from, the material of the first dielectric layer 561.

Referring to FIGS. 6A and 6B, the processing steps described with reference to FIGS. 4A and 4B may be performed to pattern the composite tunneling dielectric layer 56L and the control gate electrode material layer 58L. Each remaining portion of the control gate electrode material layer 58L comprises a control gate electrode 58, and each remaining portion of the composite tunneling dielectric layer 56L comprises a composite tunneling dielectric 56. Each control gate electrode 58 may comprise a stack of a metallic control gate electrode portion 58M and a semiconductor control gate electrode portion 58S. A stack of a composite tunneling dielectric 56 and a control gate electrode 58 is formed underneath each patterned portion of the photoresist layer 57. Each of the composite tunneling dielectric 56 and the control gate electrode 58 may have a uniform width along the first horizontal direction hd1, which is herein referred to as a first width w1. The first width w1 may be in a range from 20 nm to 120 nm, although lesser and greater widths may also be used. The photoresist layer 57 may be subsequently removed, for example, by ashing.

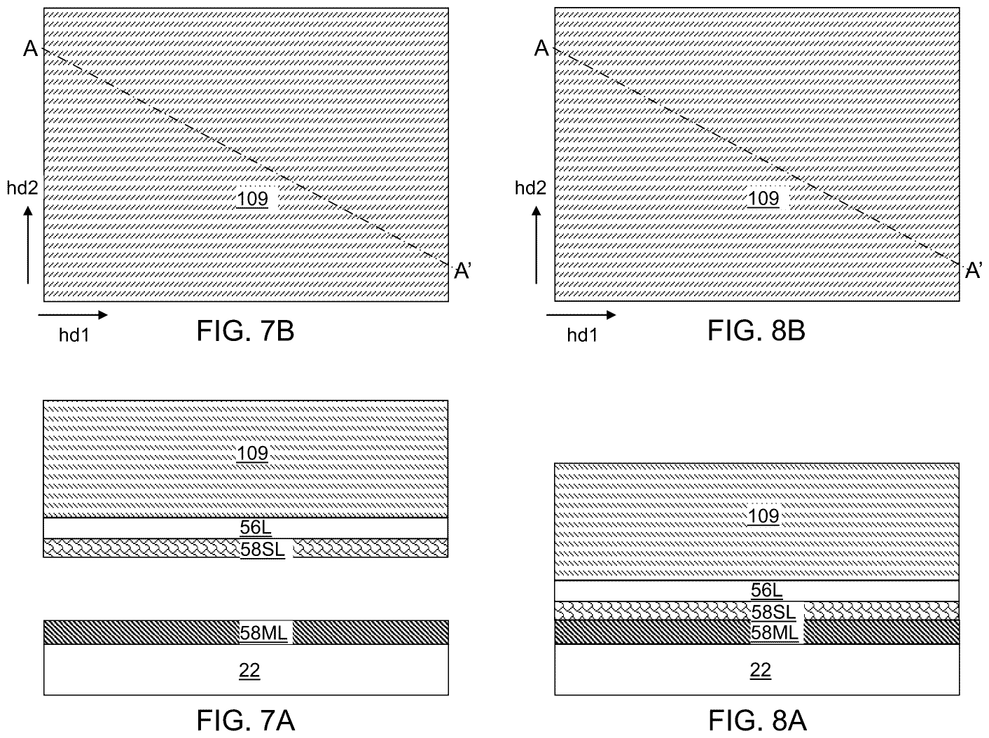

Referring to FIGS. 7A and 7B, a third configuration of the first embodiment structure is illustrated. The third configuration of the first embodiment structure may be derived from the first embodiment structure illustrated in FIG. 7A by depositing a metallic control gate electrode material layer 58ML on a top surface of the insulating layer 22. The material composition and the thickness of the metallic control gate electrode material layer 58ML may be the same as described with reference to FIGS. 5A and 5B. The metallic control gate electrode material layer 58ML is provided on a first wafer, such as a substrate 8 described with reference to FIG. 1.

In addition, a second wafer is provided, which comprises a carrier substrate 109, an optional adhesive layer (not shown) that is formed on a top surface of the carrier substrate 109, a composite tunneling dielectric layer 56L that is formed on the carrier substrate 109 or on the adhesive layer, and a semiconductor control gate electrode material layer 58SL. The carrier substrate 109 may be any substrate that may be subsequently removed, for example, by cleaving or by material removal (e.g., by grinding, polishing, and/or etching). The adhesive layer, in instance in which it is present, may comprise an adhesive material that may be thermally decomposed, or may be inactivated upon ultraviolet irradiation. For example, the carrier substrate 109 may comprise a commercially available silicon substrate or a glass substrate.

The composite tunneling dielectric layer 56L may be the same as in the first configuration of the first embodiment structure described with reference to FIGS. 2A, 2B, and 3A-3C. Thus, the composite tunneling dielectric layer 56L in the second configuration of the first embodiment structure illustrated in FIGS. 5A and 5B may have any configuration described with reference to FIGS. 3A-3C. The conduction band offsets of each material within the composite tunneling dielectric layer 56L may be measured relative to the Fermi energy of the conductive material within the semiconductor control gate electrode material layer 58SL. As discussed above, the material of the first dielectric layer 561 and the material of the second dielectric layer 562 are selected such that the first conduction band offset is greater than the second conduction band offset by at least 2.00 eV. In one embodiment, the first dielectric layer 561 comprises a material selected from AlN and Al₂O₃, and the second dielectric layer 562 comprises a material selected from Ta₂O₅, Ga₂O₃, Nb₂O₅, TiO₂, and SiTiO₃. In embodiments in which an additional third dielectric layer 563 is present, the third conduction band offset is greater than the second conduction band offset by at least 2.00 eV, and may comprise a material selected from AlN and Al₂O₃. The material of the additional third dielectric layer 563 may be the same as, or may be different from, the material of the first dielectric layer 561.

The material composition and the thickness of the semiconductor control gate electrode material layer 58SL may be the same as described with reference to FIGS. 5A and 5B. The second wafer and the first wafer may be aligned such that a physically exposed planar surface of the metallic control gate electrode material layer 58ML faces the physically exposed planar surface of the semiconductor control gate electrode material layer 58SL.

Referring to FIGS. 8A and 8B, the first wafer and the second wafer may be bonded to each other. For example, a thermocompressive bonding process may be performed to induce bonding between the metallic control gate electrode material layer 58ML and the semiconductor control gate electrode material layer 58SL. In some embodiments, a metal-semiconductor alloy layer (not illustrated) may be formed as an interfacial material layer between the metallic control gate electrode material layer 58ML and the semiconductor control gate electrode material layer 58SL.

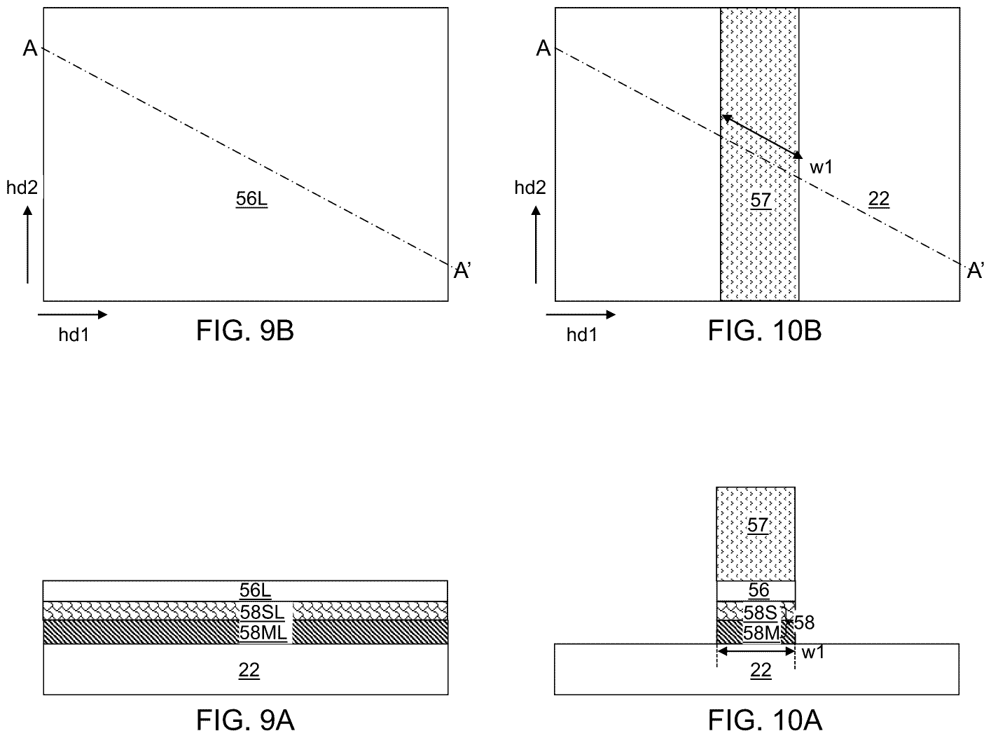

Referring to FIGS. 9A and 9B, the carrier substrate 109 may be removed by cleaving (e.g., by deactivating an adhesive layer) or by removal of the material of the carrier substrate 109 (e.g., by grinding, polishing, and/or etching). A planar surface of the composite tunneling dielectric layer 56L is exposed. In one embodiment, the third configuration of the first embodiment structure at this processing step may be the same as the second configuration of the first embodiment structure after the processing steps of FIGS. 5A and 5B.

Referring to FIGS. 10A and 10B, the processing steps described with reference to FIGS. 4A and 4B may be performed to pattern the composite tunneling dielectric layer 56L and the control gate electrode material layer 58L. Each remaining portion of the control gate electrode material layer 58L comprises a control gate electrode 58, and each remaining portion of the composite tunneling dielectric layer 56L comprises a composite tunneling dielectric 56. Each control gate electrode 58 may comprise a stack of a metallic control gate electrode portion 58M and a semiconductor control gate electrode portion 58S. A stack of a composite tunneling dielectric 56 and a control gate electrode 58 is formed underneath each patterned portion of the photoresist layer 57. Each of the composite tunneling dielectric 56 and the control gate electrode 58 may have a uniform width along the first horizontal direction hd1, which is herein referred to as a first width w1. The first width w1 may be in a range from 20 nm to 120 nm, although lesser and greater widths may also be used. The photoresist layer 57 may be subsequently removed, for example, by ashing.

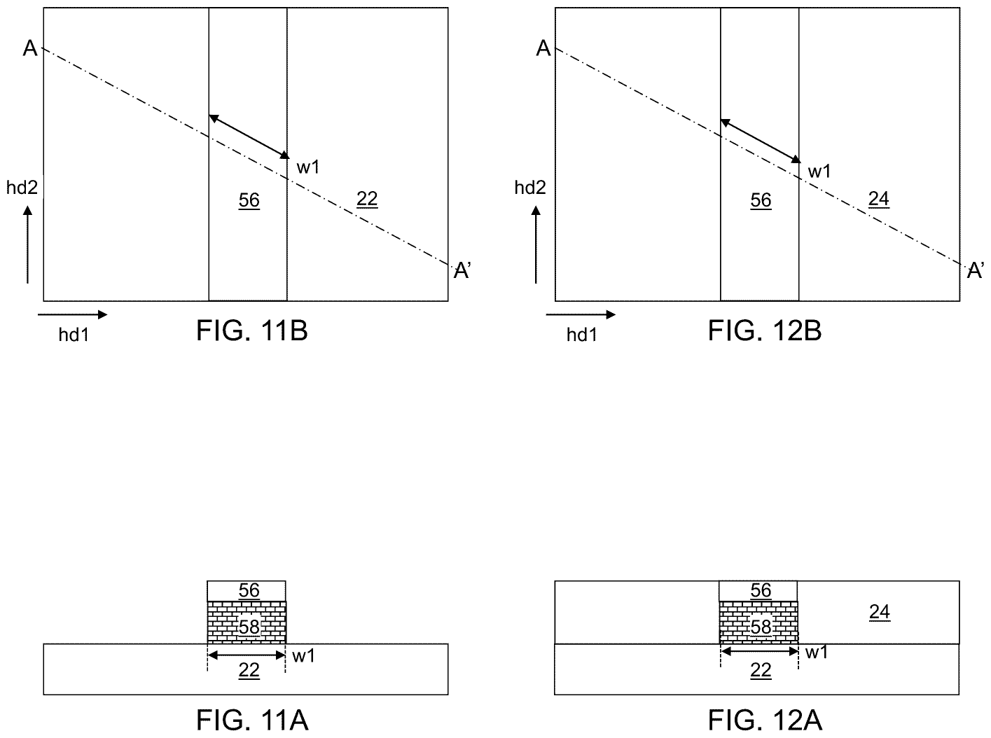

Referring to FIGS. 11A and 11B, the first embodiment structure is illustrated after formation of a control gate electrode 58 and a composite tunneling dielectric 56. Generally, the first embodiment structure illustrated in FIGS. 11A and 11B may be the same as any configuration of the first embodiment structure, and as such, may be derived from the first embodiment structure illustrated in FIGS. 4A and 4B, 6A and 6B, or 10A and 10B by removing the photoresist layer 57. Further, it is understood that the illustrated area in FIG. 11B corresponds to the area of unit memory cell within a periodic two-dimensional array of memory cells to be subsequently formed.

Referring to FIGS. 12A and 12B, a dielectric matrix layer 24 may be formed around the stack of the control gate electrode 58 and the composite tunneling dielectric 56 and over the insulating layer 22 and the lower interconnect-level dielectric material layers. The dielectric matrix layer 24 comprises a planarizable dielectric material. In one embodiment, the dielectric matrix layer 24 comprises a self-planarizing dielectric material such as flowable oxide (FOx). The amount of the precursor material applied around the stack of the control gate electrode 58 and the composite tunneling dielectric 56 may be selected such that the top surface of the dielectric matrix layer 24 is coplanar with the top surface of the composite tunneling dielectric 56 upon curing of the applied precursor material.

Alternatively, the dielectric matrix layer 24 may be forming by depositing a dielectric material such as undoped silicate glass or a doped silicate glass around, and over, the stack of the control gate electrode 58 and the composite tunneling dielectric 56, and by removing portions of the dielectric material from above the horizontal plane including the top surface of the composite tunneling dielectric 56 by performing a planarization process. In this embodiment, the dielectric matrix layer 24 may be formed around, and over, the control gate electrode 58 and the composite tunneling dielectric 56, and the dielectric matrix layer 24 may be subsequently planarized by removing portions of the dielectric matrix layer 24 from above the horizontal plane including a top surface of the composite tunneling dielectric 56 by performing at least one planarization process. The at least one planarization process may comprise a chemical mechanical polishing (CMP) process followed by an etch process, which may include a wet etch process or a dry etch process. Upon planarization, the dielectric matrix layer 24 laterally surrounds the control gate electrode 58 and the composite tunneling dielectric 56, and the top surface of the dielectric matrix layer 24 may be coplanar with a top surface of the composite tunneling dielectric 56.

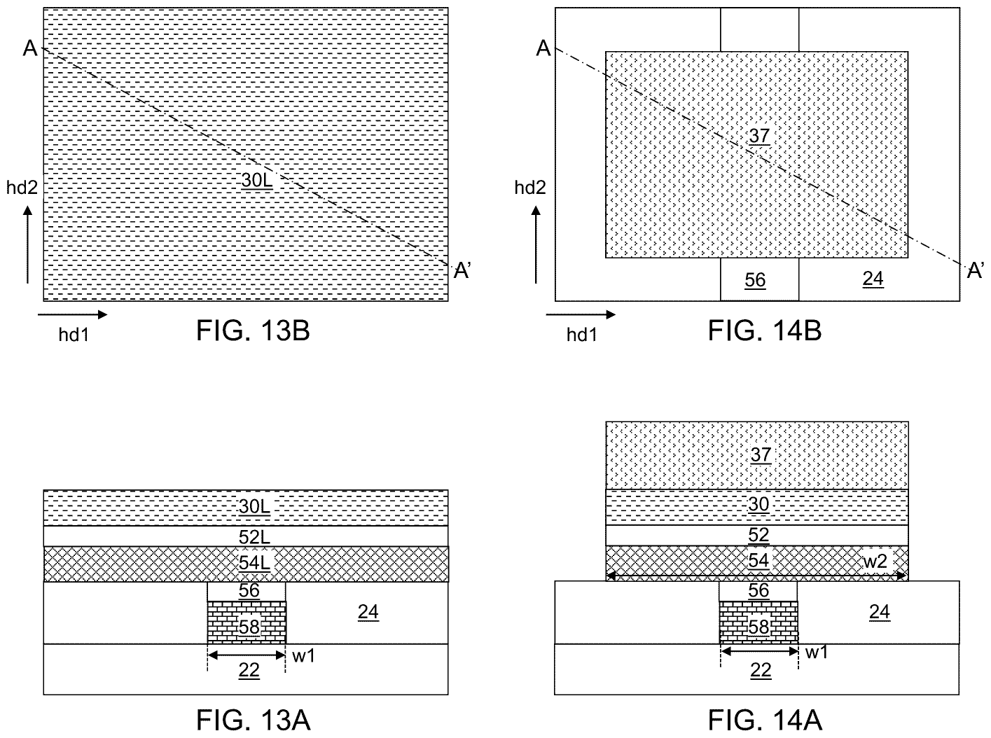

Referring to FIGS. 13A and 13B, a layer stack including, from bottom to top, a floating gate electrode material layer 54L, a blocking dielectric layer 52L, and a semiconductor layer 30L may be deposited. The floating gate electrode material layer 54L comprises at least one conductive material such as titanium nitride, tantalum nitride, a titanium aluminum alloy, a heavily doped semiconductor material (e.g., heavily doped polysilicon), or a combination thereof. The thickness of the floating gate electrode material layer 54L may be in a range from 4 nm to 20 nm, although lesser and greater thicknesses may also be used.

The blocking dielectric layer 52L comprises a gate dielectric material that may block charge tunneling therethrough. The blocking dielectric layer 52L may comprise a dielectric metal oxide material having a dielectric constant greater than 7.9, i.e., a high-k dielectric material. Exemplary materials that may be used for the blocking dielectric layer 52L include aluminum oxide, hafnium oxide, hafnium zirconium oxide, zirconium oxide, titanium oxide, tantalum oxide, lanthanum oxide, yttrium oxide, etc. Other dielectric materials may be within the contemplated scope of disclosure. The thickness of the blocking dielectric layer 52L may be in a range from 4 nm to 12 nm, although lesser and greater thicknesses may also be used.

The semiconductor layer 30L may comprise a semiconductor material, which may be single crystalline, poly crystalline, or amorphous. In one embodiment, the semiconducting material may comprise a compound semiconducting metal oxide material, e.g., indium gallium zinc oxide (IGZO), indium oxide, tin-doped indium oxide (ITO), tungsten-doped indium oxide (IWO), gallium oxide, zinc oxide, indium zinc oxide (IZO), tin oxide, copper oxide, nickel oxide, copper chromium oxide. In one embodiment, the semiconducting material may comprise silicon, silicon germanium, or germanium. In one embodiment, the semiconducting material may comprise a compound semiconducting chalcogenide material, such as cadmium selenide, copper indium diselenide, lead sulfide, cadmium telluride, cadmium sulfide, cadmium selenide, cadmium telluride, zinc sulfide, zinc selenide, zinc telluride, lead sulfide, lead selenide, lead telluride, copper indium disulfide, copper indium selenide, copper indium gallium selenide, copper tin sulfide, copper zinc tin sulfide, bismuth telluride, antimony selenide, gallium selenide, indium selenide, molybdenum disulfide, tungsten diselenide, tin disulfide, antimony sulfide, tellurium, arsenic sulfide, bismuth selenide, and bismuth telluride. In one embodiment, the semiconductor material may comprise a two-dimensional semiconducting material such as graphene, molybdenum disulfide, molybdenum diselenide, tungsten disulfide, tungsten diselenide and tellurium. Other semiconducting materials are within the contemplated scope of this disclosure. The thickness of the semiconductor layer 30L may be in a range from 4 nm to 20 nm. The semiconductor layer 30L may be deposited by physical vapor deposition, chemical vapor deposition, or atomic layer deposition.

Referring to FIGS. 14A and 14B, an etch mask 37 may be formed over the semiconductor layer 30L. The etch mask 37 may comprise a lithographically patterned photoresist layer covering area of the semiconductor layer 30L to be subsequently patterned into active layers. In one embodiment, the etch mask 37 may cover a rectangular region within each area of a unit memory cell (such as the area illustrated in FIG. 14B).

An anisotropic etch process may be performed to etch portions of the semiconductor layer 30L, the blocking dielectric layer 52L, and the floating gate electrode material layer 54L that are not masked by the etch mask 37. A stack including a floating gate electrode 54, a blocking dielectric 52, and an active layer 30 may be formed underneath each portion of the etch mask 37. A patterned portion of the semiconductor layer 30L comprises the active layer 30. A patterned portion of the blocking dielectric layer 52L comprises the blocking dielectric 52. A patterned portion of the floating gate electrode material layer 54L comprises the floating gate electrode 54. Sidewalls of the floating gate electrode 54, the blocking dielectric 52, and the active layer 30 may be vertically coincident with one another, i.e., may be formed within a same set of vertical planes. The lateral dimension of each of the floating gate electrode 54, the blocking dielectric 52, and the active layer 30 along the second horizonal direction hd1 is herein referred to as a second width w2, which may be greater than, or may be the same as, the first width w1. The second width w2 may be in a range from 60 nm to 200 nm, although lesser and greater dimensions may also be used. The etch mask 37 may be subsequently removed, for example, by ashing.

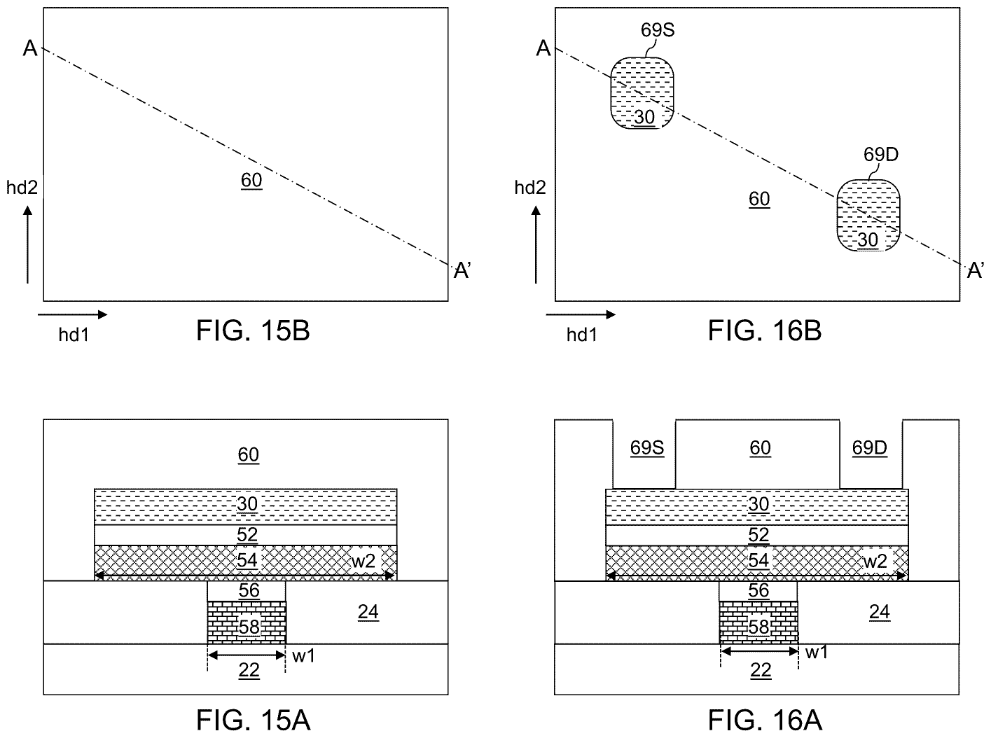

Referring to FIGS. 15A and 15B, a dielectric material such as undoped silicate glass, a doped silicate glass, organosilicate glass, silicon nitride, silicon carbide nitride, or a combination thereof may be deposited over the patterned stack of the floating gate electrode 54, the blocking dielectric 52, and the active layer 30. Optionally, the top surface of the dielectric material may be planarized, for example, by performing a chemical mechanical polishing process. The dielectric material layer including a remaining portion of the deposited dielectric material is herein referred to as a contact-level dielectric layer 60. The vertical distance between the top surface of the contact-level dielectric layer 60 and the top surface of the active layer 30 may be in a range from 20 nm to 100 nm, although lesser and greater vertical distances may also be used.

Referring to FIGS. 16A and 16B, a photoresist layer (not shown) may be applied over the contact-level dielectric layer 60, and may be lithographically patterned to form openings over each area of the active layers 30. A pair of openings may be formed above each active layer 30 such that a surface segment of a first end of the top surface of the active layer 30 is physically exposed underneath a first opening through the contact-level dielectric layer 60, and a surface segment of a second end of the top surface of the active layer 30 is physically exposed underneath a second opening through the contact-level dielectric layer 60. The first opening is herein referred to as source contact via cavity 69S, and the second opening is herein referred to as a drain contact via cavity 69D. The source contact via cavity 69S and the drain contact via cavity 69D are laterally spaced from each other along the first horizontal direction hd1. Optionally, the source contact via cavity 69S and the drain contact via cavity 69D are laterally spaced from each other along the second horizontal direction hd2.

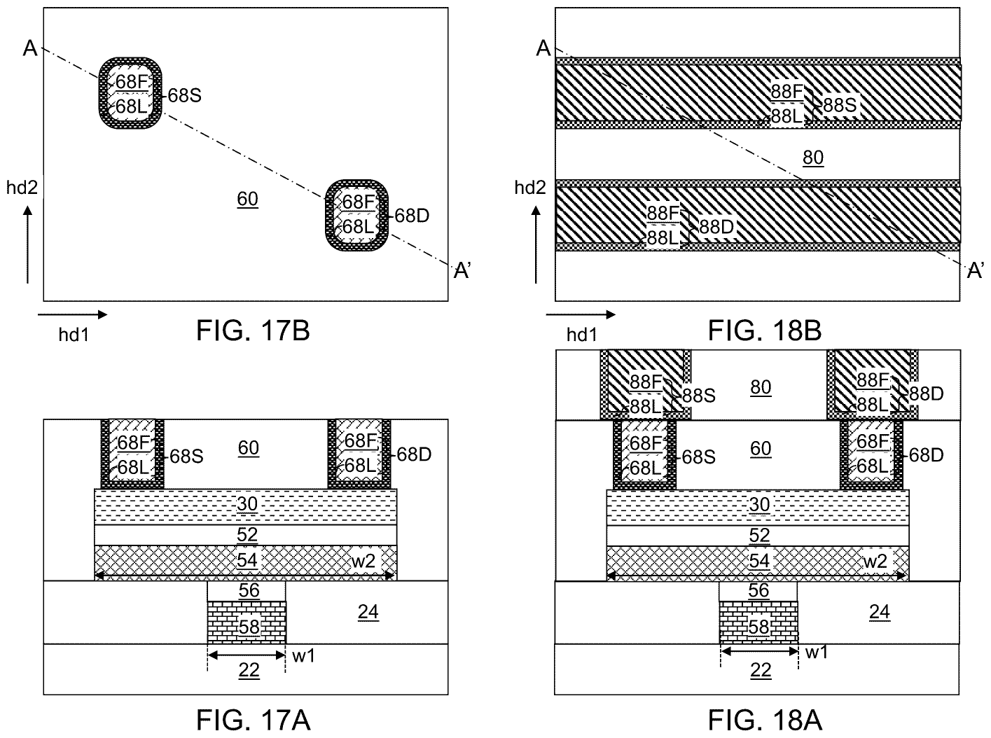

Referring to FIGS. 17A and 17B, a conductive barrier material layer and a conductive fill material layer may be deposited in the source contact via cavity 69S and in the drain contact via cavity 69D. Excess portions of the conductive barrier material layer and the conductive fill material layer may be removed from above the horizontal plane including the top surface of the contact-level dielectric layer 60 by performing a planarization process, which may use a chemical mechanical polishing process and/or a recess etch process. Each remaining portion of the conductive barrier material layer and the conductive fill material layer filling the source contact via cavity 69S constitutes a source contact structure 68S. Each remaining portion of the conductive barrier material layer and the conductive fill material layer filling the drain contact via cavity 69D constitutes a drain contact structure 68D.

Each of the source contact structure 68S and the drain contact structure 68D comprises a combination of a conductive barrier liner 68L and a conductive fill material portion 68F. Each conductive barrier liner 68L is a remaining portion of the conductive barrier material layer, and as such, comprises a conductive barrier material. The conductive barrier material of each conductive barrier liner 68L may comprise a heavily doped compound metal oxide material such as InGaZnO, InO, InSnO, InZnO, or InWO with heavy doping, or may comprise a conductive metallic nitride material such as TiN, TaN, WN, MON, etc. The thickness of each conductive barrier liner 68L may be in a range from 3 nm to 10 nm, although lesser and greater thicknesses may also be used. Each conductive fill material portion 68F may comprise titanium nitride, tungsten, copper, ruthenium, cobalt, nickel, or a metal silicide material.

Generally, within each area of unit memory cell, a source contact structure 68S may be formed through the contact-level dielectric layer 60 on a first top end of the active layer 30, and a drain contact structure 68D may be formed through the contact-level dielectric layer 60 on a second top end of the active layer 30. The top surfaces of the source contact structure 68S and the drain contact structure 68D may be formed within the horizontal plane including the top surface of the contact-level dielectric layer 60.

Referring to FIGS. 18A and 18B, a line-level dielectric layer 80 may be formed over the contact-level dielectric layer 60 by depositing a dielectric material such as undoped silicate glass, a doped silicate glass, organosilicate glass, silicon nitride, silicon carbide nitride, or a combination thereof. The thickness of the line-level dielectric layer 80 may be in a range from 20 nm to 100 nm, although lesser and greater vertical distances may also be used.

Line trenches laterally extending along the first horizontal direction hd1 may be formed through the line-level dielectric layer 80 over each of the source contact structure 68S and the drain contact structure 68D. For example, a photoresist layer (not shown) may be applied over the line-level dielectric layer 80, and may be lithographically patterned into a line-and-space pattern that laterally extends along the first horizontal direction hd1, and is repeated along the second horizontal direction hd2. Each of the source contact structure 68S and the drain contact structure 68D may be located underneath a respective space between a neighboring pair of line-shaped patterned photoresist material portions. An anisotropic etch process may be performed to transfer the pattern of the spaces within the line-and-space pattern though the line-level dielectric layer 80. A source line trench is formed above the source contact structure 68S, and a drain line trench is formed above the drain contact structure 68D.

A conductive barrier material layer and a conductive fill material layer may be deposited in the source line trench and in the drain line trench. Excess portions of the conductive barrier material layer and the conductive fill material layer may be removed from above the horizontal plane including the top surface of the line-level dielectric layer 80 by performing a planarization process, which may use a chemical mechanical polishing process and/or a recess etch process. Each remaining portion of the conductive barrier material layer and the conductive fill material layer filling the source line trench constitutes a source line 88S. Each remaining portion of the conductive barrier material layer and the conductive fill material layer filling the drain line trench constitutes a drain line 88D.

Each of the source line 88S and the drain line 88D comprises a combination of a conductive barrier liner 88L and a conductive fill material portion 88F. Each conductive barrier liner 88L is a remaining portion of the conductive barrier material layer, and as such, comprises a conductive barrier material. The conductive barrier material of each conductive barrier liner 88L may comprise a conductive metallic nitride material such as TiN, TaN, WN, MON, etc. The thickness of each conductive barrier liner 88L may be in a range from 3 nm to 10 nm, although lesser and greater thicknesses may also be used. Each conductive fill material portion 88F may comprise titanium nitride, tungsten, copper, ruthenium, cobalt, nickel, or a metal silicide material. The source line 88S may be formed through the line-level dielectric layer 80 on a top surface of the source contact structure 68S, and the drain line 88D may be formed through the line-level dielectric layer 80 on a top end of the drain contact structure 68D. The top surfaces of the source line 88S and the drain line 68D may be formed within the horizontal plane including the top surface of the line-level dielectric layer 80.

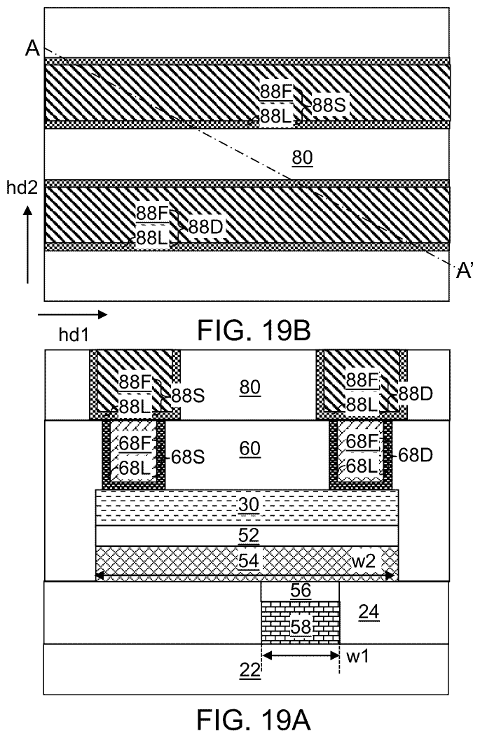

Referring to FIGS. 19A and 19B, an alternative configuration of the first embodiment structure may be derived from the first embodiment structure illustrated in FIGS. 18A and 18B by off-centering the stack of the control gate electrode 58 and the composite tunneling dielectric 56 relative to the geometrical center of the active layer 30 along the lateral separation direction between the source contact structure 68S and the drain contact structure 68D. In the illustrated example, the lateral offset direction is the first horizontal direction hd1. The lateral offset of the control gate electrode 58 and the composite tunneling dielectric 56 relative to the geometrical center of the active layer 30 along the lateral separation direction between the source contact structure 68S and the drain contact structure 68D may be used to provide modified device characteristic for the flash memory cell of the present disclosure.

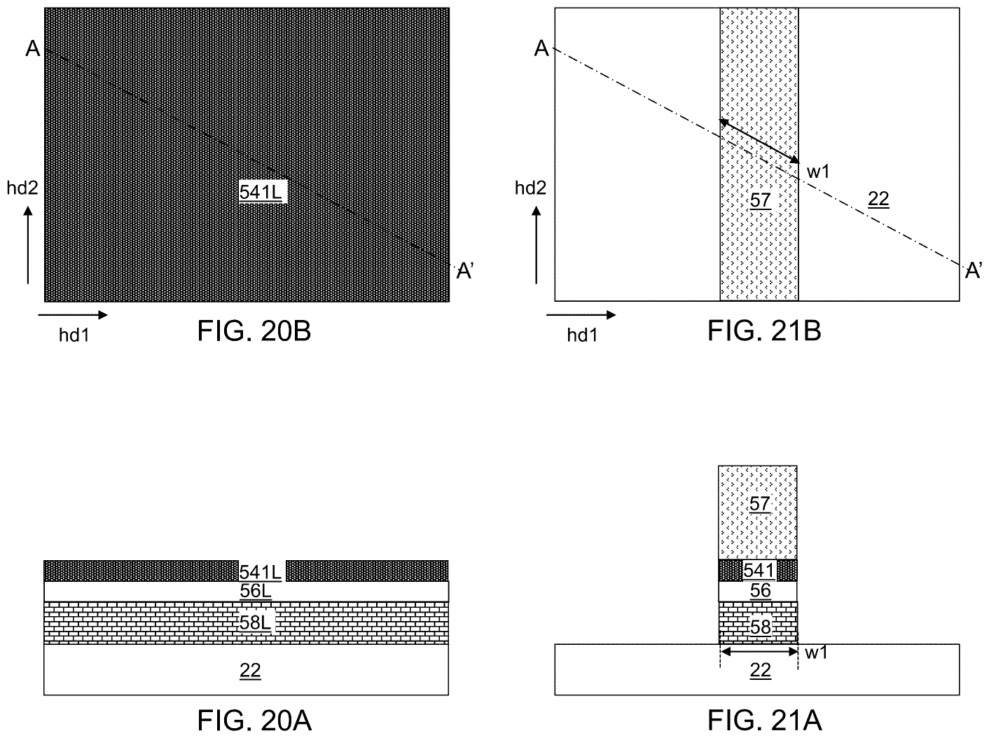

Referring to FIGS. 20A and 20B, a first configuration of a second embodiment structure is illustrated, which may be derived from the first embodiment structure illustrated in FIGS. 2A and 2B by depositing a first floating gate electrode material layer 541L on a top surface of the composite tunneling dielectric layer 56L. The first floating gate electrode material layer 541L may comprise any material that may be used for the floating gate electrode material layer 54L described above. For example, the first floating gate electrode material layer 541L may comprise titanium nitride, tantalum nitride, a titanium aluminum alloy, a heavily doped semiconductor material (e.g., heavily doped polysilicon), or a combination thereof. The thickness of the first floating gate electrode material layer 541L may be in a range from 2 nm to 15 nm, although lesser and greater thicknesses may also be used.

Referring to FIGS. 21A and 21B, the processing steps described with reference to FIGS. 4A and 4B may be performed to pattern the first floating gate electrode material layer 541L, the composite tunneling dielectric layer 56L, and the control gate electrode material layer 58L. A patterned stack including a control gate electrode 58, a composite tunneling dielectric 56, and a first floating gate electrode portion 541 may be formed. The photoresist layer 57 may be subsequently removed, for example, by ashing.

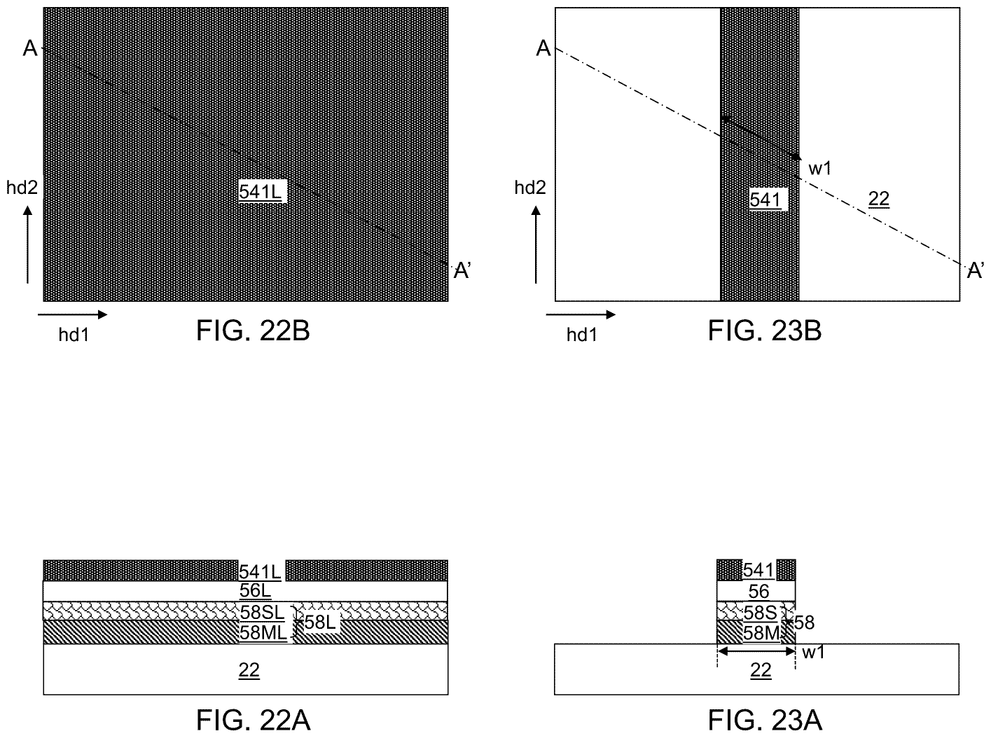

Referring to FIGS. 22A and 22B, a second configuration of the second embodiment structure is illustrated, which may be derived from any of the first embodiment structures illustrated in FIGS. 5A and 5B and FIGS. 9A and 9B by depositing a first floating gate electrode material layer 541L on a top surface of the composite tunneling dielectric layer 56L. The first floating gate electrode material layer 541L may comprise any material that may be used for the floating gate electrode material layer 54L described above. For example, the first floating gate electrode material layer 541L may comprise as titanium nitride, tantalum nitride, a titanium aluminum alloy, a heavily doped semiconductor material (e.g., heavily doped polysilicon), or a combination thereof. The thickness of the first floating gate electrode material layer 541L may be in a range from 2 nm to 15 nm, although lesser and greater thicknesses may also be used.

Referring to FIGS. 23A and 23B, the processing steps described with reference to FIGS. 6A and 6B or FIGS. 10A and 10B may be performed to pattern the first floating gate electrode material layer 541L, the composite tunneling dielectric layer 56L, and the control gate electrode material layer 58L. A patterned stack including a control gate electrode 58, a composite tunneling dielectric 56, and a first floating gate electrode portion 541 may be formed. The photoresist layer 57 may be subsequently removed, for example, by ashing.

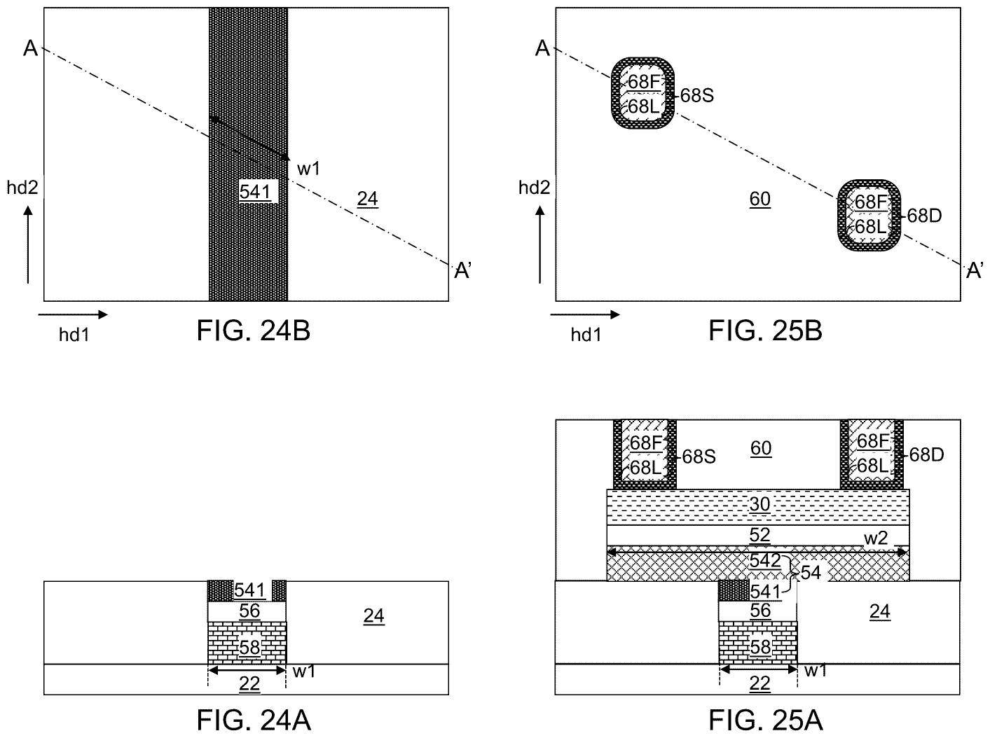

Referring to FIGS. 24A and 24B, the processing steps described with reference to FIGS. 12A and 12B may be performed on the second embodiment structure of FIGS. 21A and 21B or on the second embodiment structure of FIGS. 23A and 23B to form a dielectric matrix layer 24. The dielectric matrix layer 24 laterally surrounds the control gate electrode 58, the composite tunneling dielectric 56, and the first floating gate electrode portion 541, and the top surface of the dielectric matrix layer 24 may be coplanar with a top surface of the first floating gate electrode portion 541.

Referring to FIGS. 25A and 25B, the processing steps described with reference to FIGS. 13A and 13B and FIGS. 14A and 14B may be performed. In the second embodiment structure, the floating gate electrode 54 described with reference to FIGS. 14A and 14B functions as a second portion of a floating gate electrode, and is herein referred to as a second floating gate electrode portion 542. The second floating gate electrode portion 542 is formed directly on the top surface of the first floating gate electrode portion 541. The combination of the first floating gate electrode portion 541 and the second floating gate electrode portion 542 constitutes a floating gate electrode 54 in the second embodiment structure. The first floating gate electrode portion 541 may have the first width w1 along the first horizontal direction hd1, and the second floating gate electrode portion 542 may have the second width w2 along the first horizontal direction hd2.

Subsequently, the processing steps described with reference to FIGS. 15A-17B may be performed to form a contact-level dielectric layer 60, a source contact structure 68S, and a drain contact structure 68D within each area of a unit memory cell.

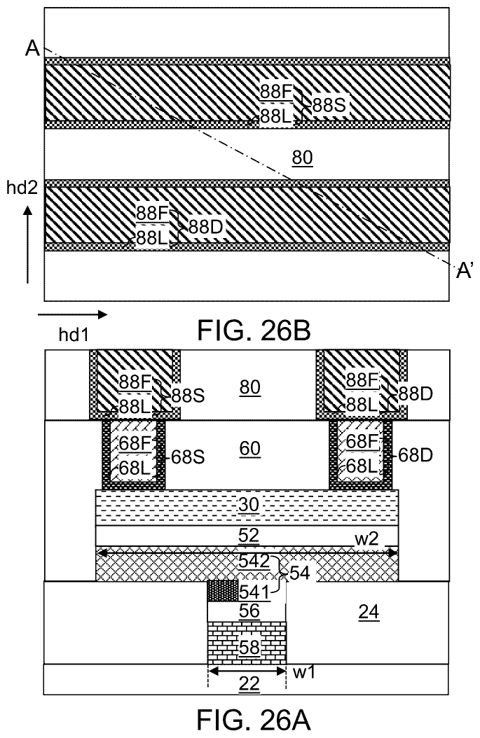

Referring to FIGS. 26A and 26B, the processing steps described with reference to FIGS. 18A and 18B or FIGS. 19A and 19B may be performed to form a line-level dielectric layer 80, a source line 88S, and a drain line 88D within each area of a unit memory cell.

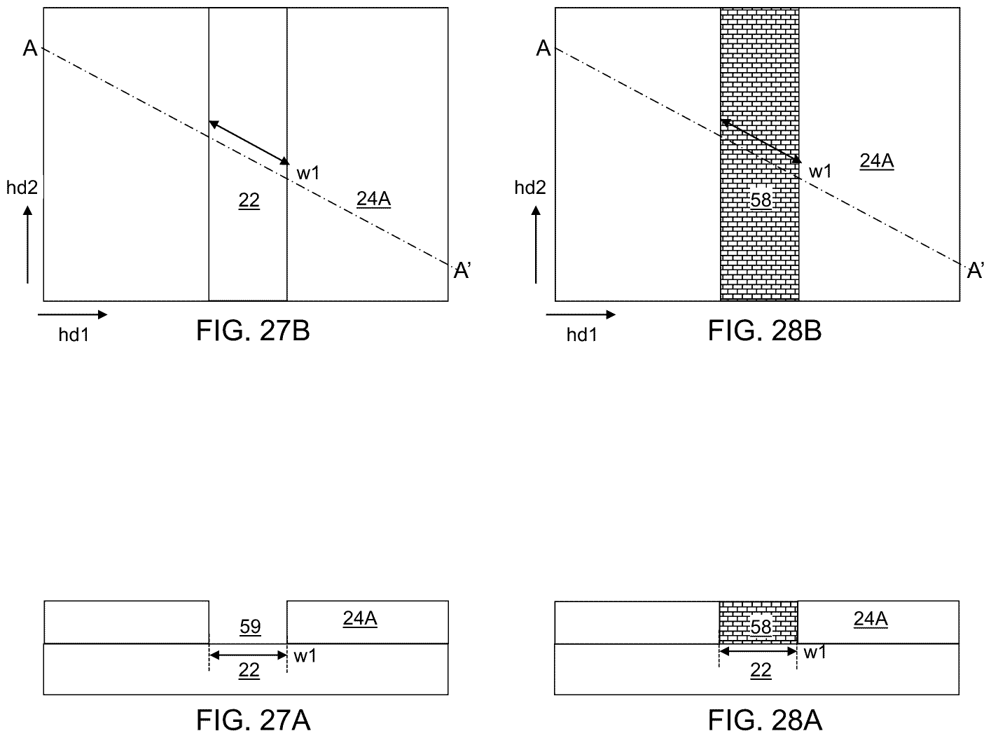

Referring to FIGS. 27A and 27B, a third embodiment structure of the present disclosure may be derived from the first embodiment structure described with reference to FIG. 1 by forming a lower dielectric matrix layer 24A above the insulating layer 22, and by forming a gate cavity 59 within a volume that corresponds to the volume of the control gate electrode 58 described with reference to FIGS. 4A and 4B. The lower dielectric matrix layer 24A comprises a dielectric material such as undoped silicate glass, a doped silicate glass, organosilicate glass, silicon carbide nitride, etc. The thickness of the lower dielectric matrix layer 24A may be in a range from 10 nm to 40 nm, although lesser and greater thicknesses may also be used. The width of the gate cavity 59 may be the same as the first width w1 described above.

Referring to FIGS. 28A and 28B, at least one conductive material may be deposited in the gate cavity 59. Excess portions of the at least one conductive material may be removed from above the horizontal plane including the top surface of the lower dielectric matrix layer 24A by performing a planarization process such as a chemical mechanical polishing process. A remaining portion of the at least one conductive material that fills the gate cavity 59 constitutes a control gate electrode 58. The top surface of the control gate electrode 58 may be coplanar with the top surface of the lower dielectric matrix layer 24A. The control gate electrode 58 of the third embodiment structure may have the same material composition as the control gate electrodes 58 in previously described embodiment structures.

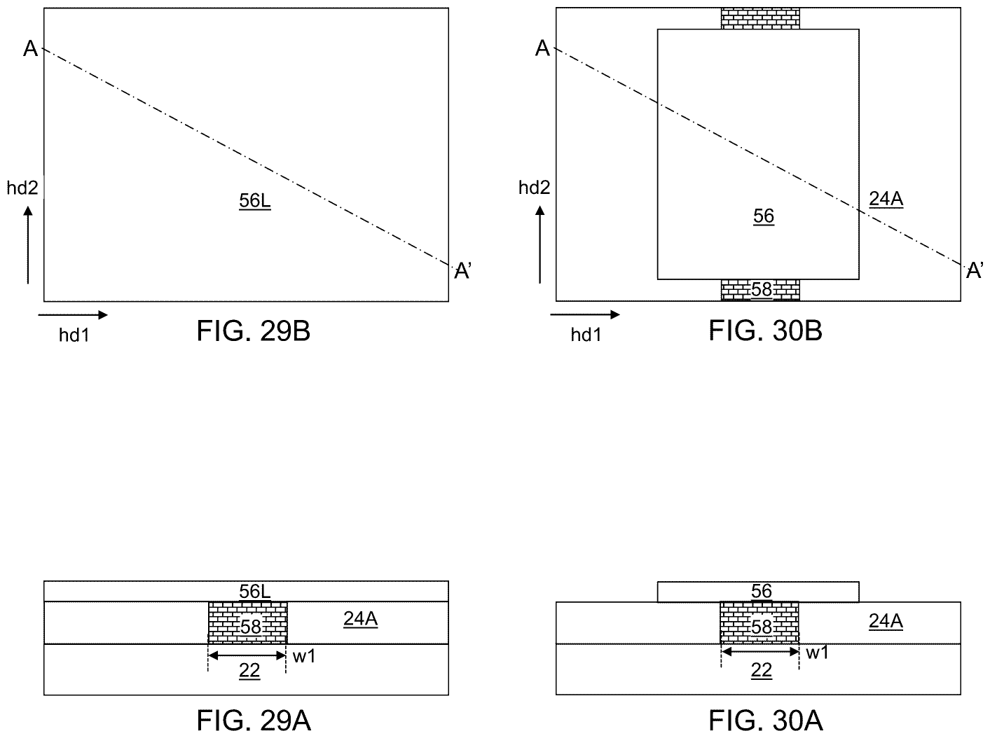

Referring to FIGS. 29A and 29B, a composite tunneling dielectric layer 56L may be formed over the control gate electrode 58 and the lower dielectric matrix layer 24A. The composite tunneling dielectric layer 56L may have any configuration described with reference to FIGS. 3A-3C.

Referring to FIGS. 30A and 30B, the composite tunneling dielectric layer 56L may be optionally patterned into a composite tunneling dielectric 56. For example, a photoresist layer (not shown) may be applied over the composite tunneling dielectric layer 56L, and may be lithographically patterned into a discrete photoresist material portion covering a center portion of the control gate electrode 58 within each area of a unit memory cell. An etch process may be performed to remove unmasked portions of the composite tunneling dielectric layer 56L. A remaining portion of the composite tunneling dielectric layer 56L constitutes the composite tunneling dielectric 56. The photoresist material portion may be subsequently removed, for example, by ashing.

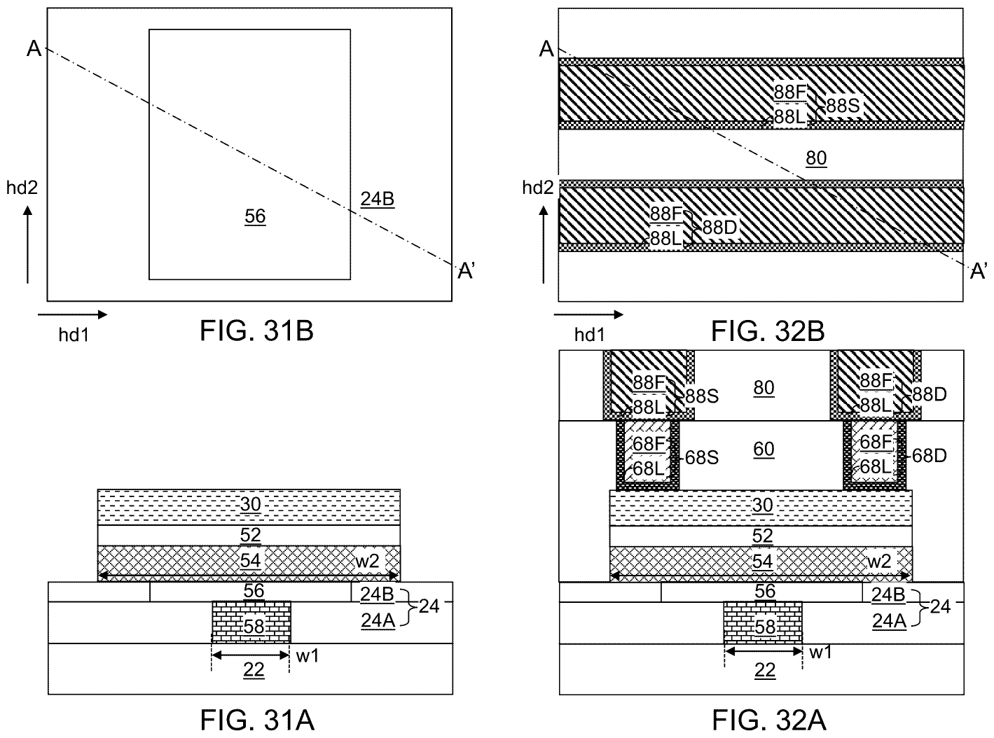

Referring to FIGS. 31A and 31B, the processing steps described with respect to FIGS. 12A and 12B may be performed with modifications in the process parameters as needed (for example, by reducing the amount of self-planarizing dielectric material in instances in which a self-planarizing dielectric material is used) to form a dielectric matrix layer, which is herein referred to as an upper dielectric matrix layer 24B. In one embodiment, the top surface of the upper dielectric matrix layer 24B may be formed within the horizontal plane including the top surface of the composite tunneling dielectric 56. The combination of the lower dielectric matrix layer 24A and the upper dielectric matrix layer 24B constitutes a dielectric matrix layer 24. The dielectric matrix layer 24 embeds the control gate electrode 58 and the composite tunneling dielectric 56, and may have a top surface that is coplanar with the top surface of the composite tunneling dielectric 56.

Subsequently, the processing steps described with reference to FIGS. 13A-14B may be performed to form a stack of a floating gate electrode 54, a blocking dielectric 52, and an active layer 30.

Referring to FIGS. 32A and 32B, the processing steps described with reference to FIGS. 15A-19B may be performed to form a contact-level dielectric layer 60, a source contact structure 68S, a drain contact structure 68D, a line-level dielectric layer 80, a source line 88S, and a drain line 88D within each area of a unit memory cell.

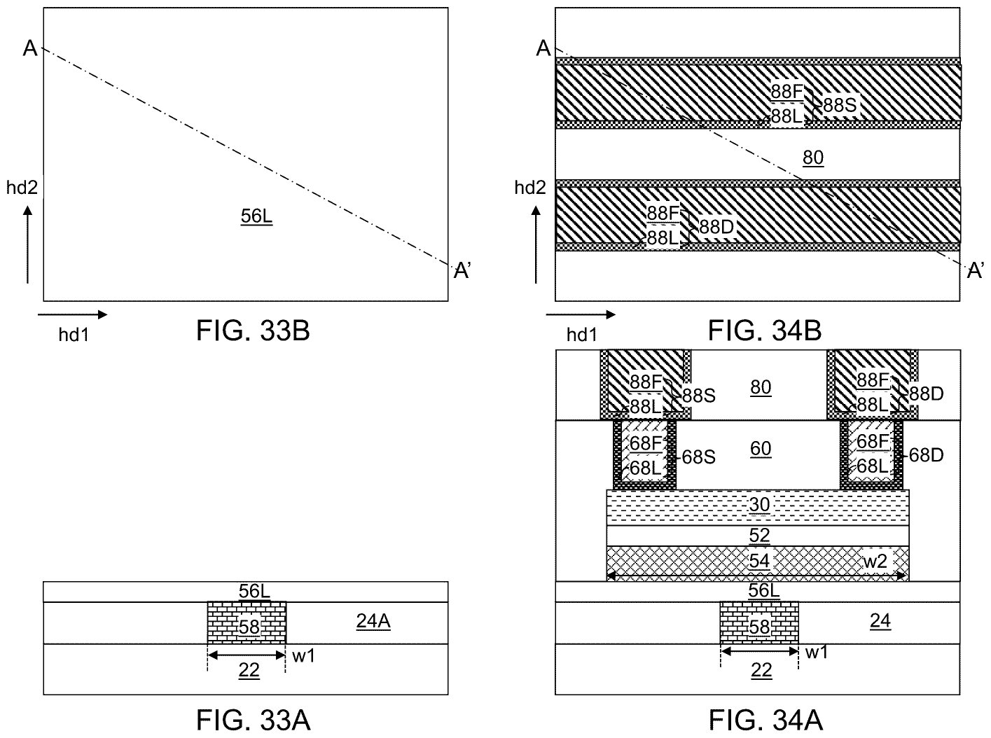

Referring to FIGS. 33A and 33B, a first alternative configuration of the third embodiment structure may be derived from the third embodiment structure described with reference to FIGS. 29A and 29B by omitting the patterning of the composite tunneling dielectric layer 56L.

Referring to FIGS. 34A and 34B, the processing steps described with reference to FIGS. 13A-14B may be performed to form a stack of a floating gate electrode 54, a blocking dielectric 52, and an active layer 30. Subsequently, the processing steps described with reference to FIGS. 15A-19B may be performed to form a contact-level dielectric layer 60, a source contact structure 68S, a drain contact structure 68D, a line-level dielectric layer 80, a source line 88S, and a drain line 88D within each area of a unit memory cell. The portion of the composite tunneling dielectric layer 56L having an areal overlap with the floating gate electrode 54 constitutes a composite tunneling dielectric.

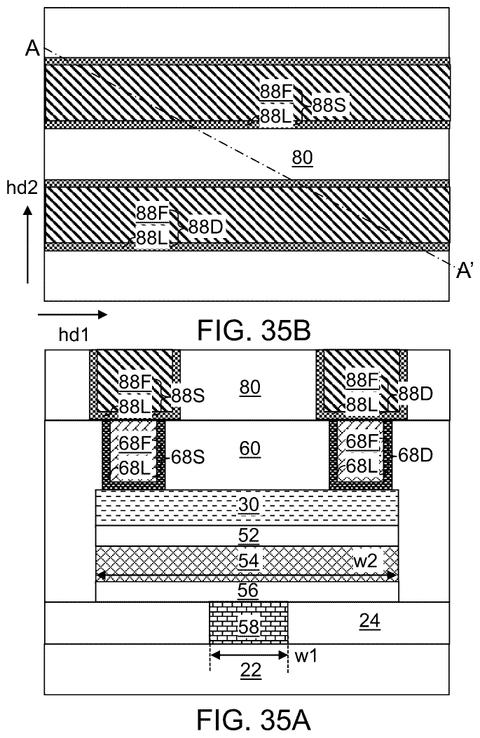

Referring to FIGS. 35A and 35B, a second alternative configuration of the third embodiment structure may be derived from the first alternative configuration of the third embodiment structure by extending an anisotropic etch process that patterns the semiconductor layer 30L, the blocking dielectric layer 52L, and the floating gate electrode material layer 54L to pattern the composite tunneling dielectric layer 56L into a composite tunneling dielectric 56. In this embodiment, the contact-level dielectric layer 60 may be formed directly on sidewalls of the composite tunneling dielectric 56.

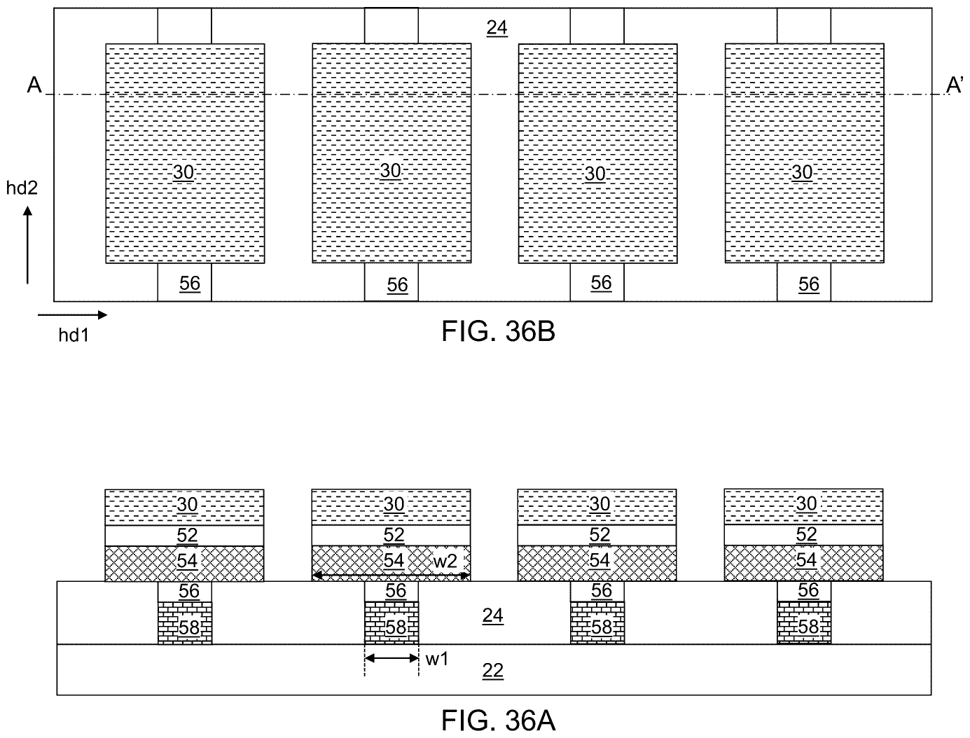

Referring to FIGS. 36A and 36B, a fourth embodiment structure is illustrated after formation of stacks of a floating gate electrode 54, a blocking dielectric 52, and an active layer 30 within each area of a unit memory cell. An area of four unit memory cells is illustrated in FIG. 36B. The fourth embodiment structure illustrated in FIGS. 36A and 36B may be derived from any of the first embodiment structure illustrated in FIGS. 14A and 14B, FIGS. 25A and 25B, and FIGS. 31A and 31B.

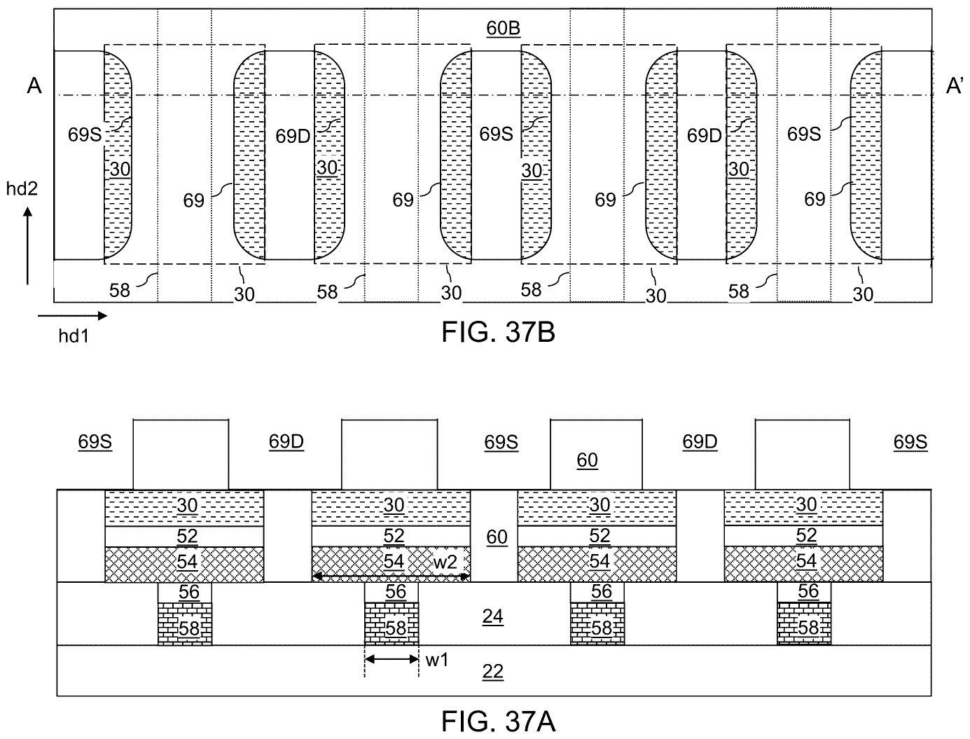

Referring to FIGS. 37A and 37B, source contact via cavities 69S and a drain contact via cavities 69D may be formed through an upper portion of the contact-level dielectric layer 60 to top surfaces of the active layers 30. According to an aspect of the present disclosure, end portions of top surfaces of a respective neighboring pair of active layers 30 may be formed underneath each of the source contact via cavities 69S and the drain contact via cavities 69D. The source contact via cavities 69S and the drain contact via cavities 69D may alternate along the first horizontal direction hd1. A top surface of each active layer 30 may have a first end surface segment that is exposed to a source contact via cavity 69S and a second end surface segment that is exposed to a drain contact via cavity 69D.

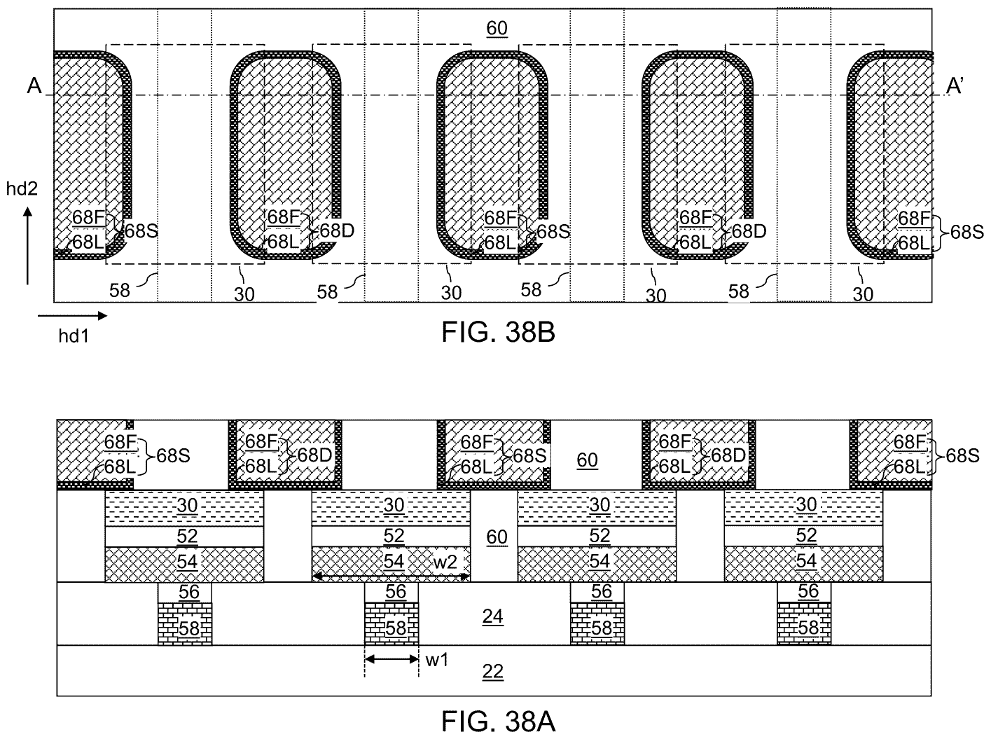

Referring to FIGS. 38A and 38B, the processing steps described with reference to FIGS. 17A and 17B may be performed to form source contact structures 68S and drain contact structures 68D in the source contact via cavities 69S and in the drain contact via cavities 69D, respectively. Each of the source contact structure 68S and the drain contact structure 68D comprises a combination of a conductive barrier liner 68L and a conductive fill material portion 68F. Each conductive barrier liner 68L is a remaining portion of the conductive barrier material layer, and as such, comprises a conductive barrier material. The conductive barrier material of each conductive barrier liner 68L may comprise a heavily doped compound metal oxide material such as InGaZnO, InO, InSnO, InZnO, or InWO with heavy doping, or may comprise a conductive metallic nitride material such as TIN, TaN, WN, MON, etc. The thickness of each conductive barrier liner 68L may be in a range from 3 nm to 10 nm, although lesser and greater thicknesses may also be used. Each conductive fill material portion 68F may comprise titanium nitride, tungsten, copper, ruthenium, cobalt, nickel, or a metal silicide material.

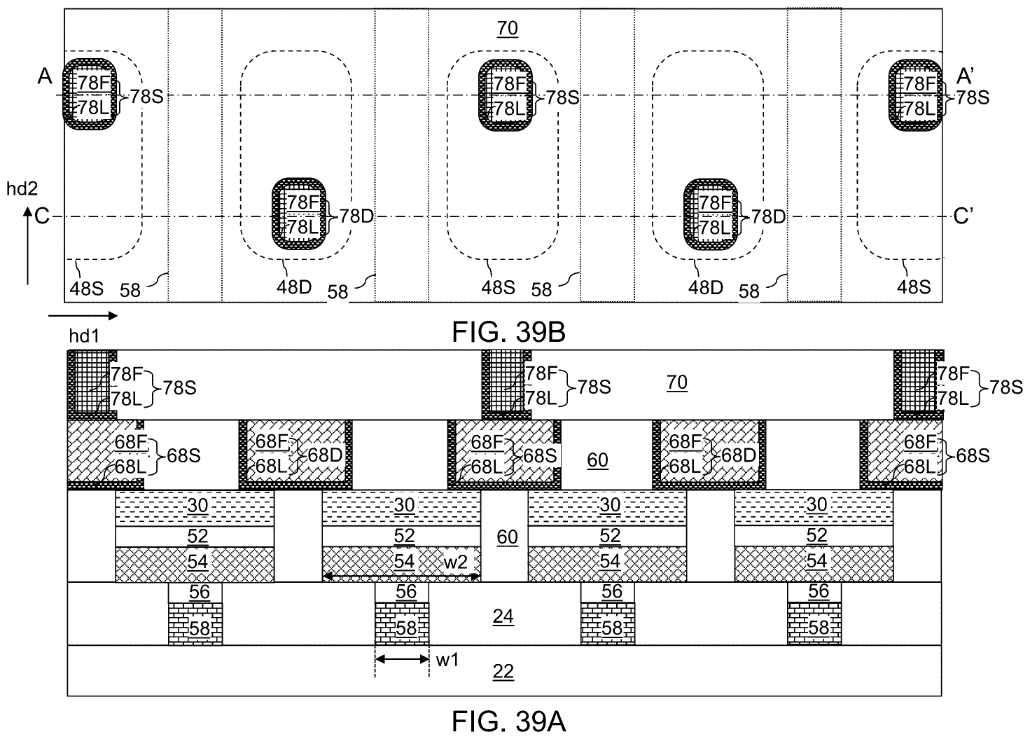

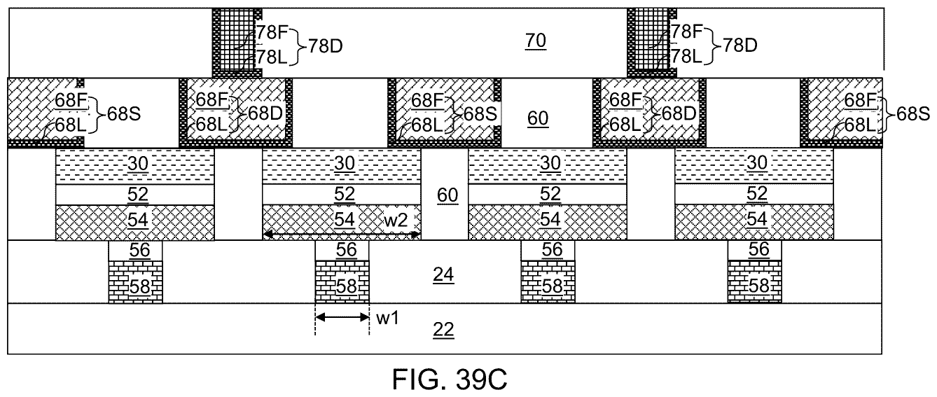

Referring to FIGS. 39A-39C, a via-level dielectric layer 70 may be formed over the contact-level dielectric layer 60 by depositing a dielectric material such as undoped silicate glass, a doped silicate glass, organosilicate glass, silicon nitride, silicon carbide nitride, or a combination thereof. The thickness of the via-level dielectric layer 70 may be in a range from 40 nm to 200 nm, although lesser and greater vertical distances may also be used.

Connection via cavities may be formed through the via-level dielectric layer 70 over each of the source contact structure 68S and the drain contact structure 68D. For example, a photoresist layer (not shown) may be applied over the via-level dielectric layer 70, and may be lithographically patterned to form discrete openings therein. An anisotropic etch process may be performed to transfer the pattern of the discrete openings in the photoresist layer though the via-level dielectric layer 70. A source connection via cavity is formed above each source contact structure 68S, and a drain connection via cavity is formed above each drain contact structure 68D. According to an aspect of the present disclosure, the source connection via cavities may be laterally offset relative to the drain connection via cavities along the second horizontal direction hd2 in a plan view such as the view of FIG. 39B.

A conductive barrier material layer and a conductive fill material layer may be deposited in the source line trench and in the drain line trench. Excess portions of the conductive barrier material layer and the conductive fill material layer may be removed from above the horizontal plane including the top surface of the via-level dielectric layer 70 by performing a planarization process, which may use a chemical mechanical polishing process and/or a recess etch process. Each remaining portion of the conductive barrier material layer and the conductive fill material layer filling a respective one of the source connection via cavities constitutes a source connection via structure 78S. Each remaining portion of the conductive barrier material layer and the conductive fill material layer filling a respective one of the drain connection via cavities constitutes a drain connection via structure 78D. In one embodiment, rows of source connection via structures 78S may be arranged along the first horizontal direction hd1, and rows of drain connection via structures 78D may be arranged along the first horizontal direction hd1. The rows of the source connection via structures 78S and the rows of drain connection via structures 78D may be interlaced along the second horizontal direction hd2.

Each of the source connection via structure 78S and the drain connection via structure 78D comprises a combination of a conductive barrier liner 78L and a conductive fill material portion 78F. Each conductive barrier liner 78L is a remaining portion of the conductive barrier material layer, and as such, comprises a conductive barrier material. The conductive barrier material of each conductive barrier liner 78L may comprise a conductive metallic nitride material such as TiN, TaN, WN, MON, etc. The thickness of each conductive barrier liner 78L may be in a range from 3 nm to 10 nm, although lesser and greater thicknesses may also be used. Each conductive fill material portion 78F may comprise titanium nitride, tungsten, copper, ruthenium, cobalt, nickel, or a metal silicide material. Each source connection via structure 78S may be formed through the via-level dielectric layer 70 on a top surface of a respective one of the source contact structures 68S, and each drain connection via structure 78D may be formed through the via-level dielectric layer 70 on a top end of a respective one of the drain contact structures 68D. The top surfaces of the source connection via structures 78S and the drain connection via structures 68D may be formed within the horizontal plane including the top surface of the via-level dielectric layer 70.

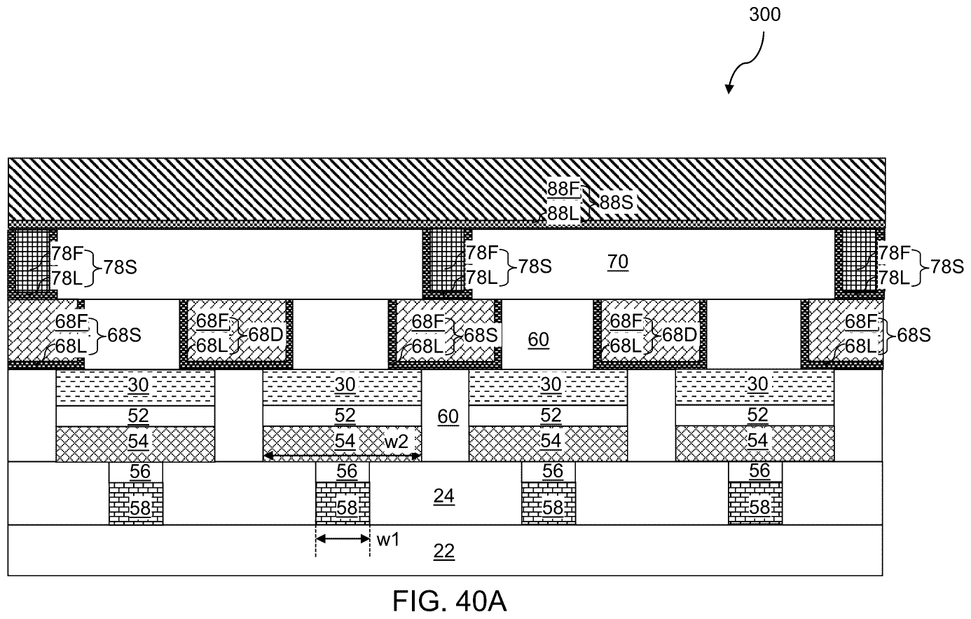

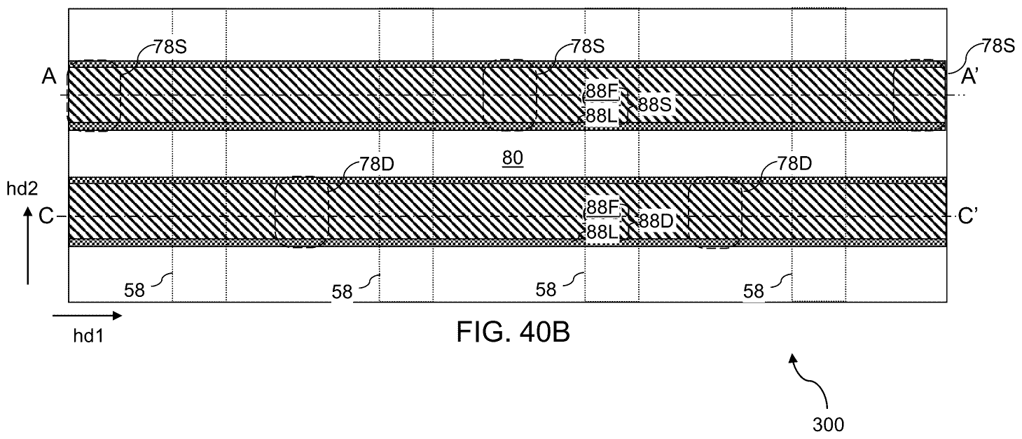

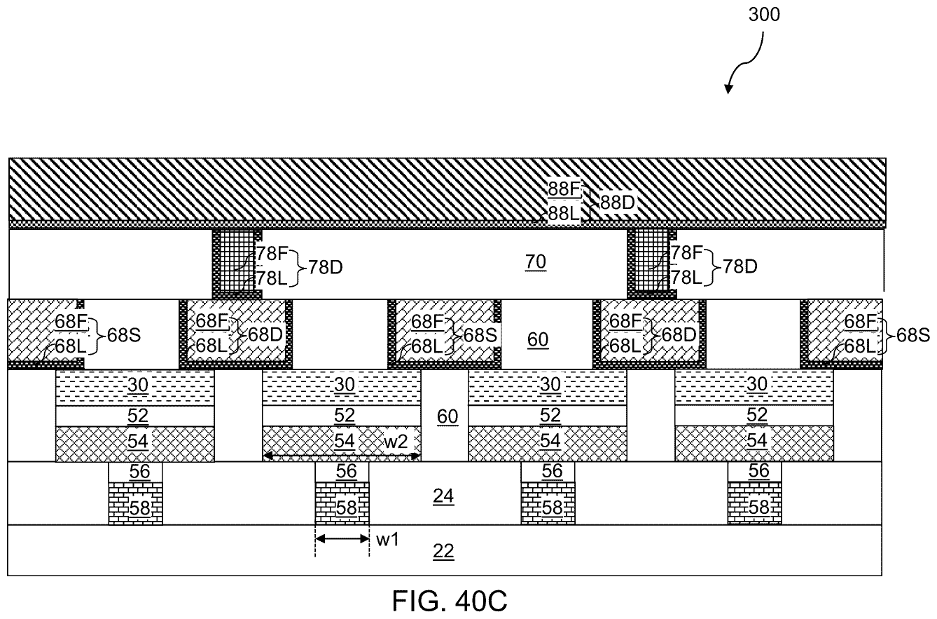

Referring to FIGS. 40A-40C, a line-level dielectric layer 80 may be formed over the via-level dielectric layer 70 by depositing a dielectric material such as undoped silicate glass, a doped silicate glass, organosilicate glass, silicon nitride, silicon carbide nitride, or a combination thereof. The thickness of the line-level dielectric layer 80 may be in a range from 20 nm to 100 nm, although lesser and greater vertical distances may also be used.

Line trenches laterally extending along the first horizontal direction hd1 may be formed through the line-level dielectric layer 80 over each of the source connection via structure 78S and the drain connection via structure 78D. For example, a photoresist layer (not shown) may be applied over the line-level dielectric layer 80, and may be lithographically patterned into a line-and-space pattern that laterally extends along the first horizontal direction hd1, and is repeated along the second horizontal direction hd2. Each of the source connection via structure 78S and the drain connection via structure 78D may be located underneath a respective space between a neighboring pair of line-shaped patterned photoresist material portions. An anisotropic etch process may be performed to transfer the pattern of the spaces within the line-and-space pattern though the line-level dielectric layer 80. A source line trench is formed above a respective row of source connection via structures 78S, and a drain line trench is formed above a respective row of drain connection via structures 78D.

A conductive barrier material layer and a conductive fill material layer may be deposited in the source line trenches and in the drain line trenches. Excess portions of the conductive barrier material layer and the conductive fill material layer may be removed from above the horizontal plane including the top surface of the line-level dielectric layer 80 by performing a planarization process, which may use a chemical mechanical polishing process and/or a recess etch process. Each remaining portion of the conductive barrier material layer and the conductive fill material layer filling a respective source line trench constitutes a source line 88S. Each remaining portion of the conductive barrier material layer and the conductive fill material layer filling a respective drain line trench constitutes a drain line 88D.

Each of the source lines 88S and the drain lines 88D comprises a combination of a conductive barrier liner 88L and a conductive fill material portion 88F. Each conductive barrier liner 88L is a remaining portion of the conductive barrier material layer, and as such, comprises a conductive barrier material. The conductive barrier material of each conductive barrier liner 88L may comprise a conductive metallic nitride material such as TiN, TaN, WN, MON, etc. The thickness of each conductive barrier liner 88L may be in a range from 3 nm to 10 nm, although lesser and greater thicknesses may also be used. Each conductive fill material portion 88F may comprise titanium nitride, tungsten, copper, ruthenium, cobalt, nickel, or a metal silicide material. Each source line 88S may be formed through the line-level dielectric layer 80 on top surfaces of a row of source connection via structures 78S, and each drain line 88D may be formed through the line-level dielectric layer 80 on top surfaces of a row of drain connection via structures 78D. The top surfaces of the source lines 88S and the drain lines 88D may be formed within the horizontal plane including the top surface of the line-level dielectric layer 80. A two-dimensional array 300 of flash memory devices may be formed.

The configuration of the two-dimensional array 300 of flash memory devices corresponds to a NOR memory array in which a row of flash memory cells are connected in a parallel connection between a source line 88S and a drain line 88D. In this configuration, any “on” state, i.e., a current-flowing state, within the row of active layers 30 that are electrically connected between the source line 88S and the drain line 88D in a parallel connection provides electrical current flow between the source line 88S and the drain line 88D. During a read operation, a selected control gate electrode 58 is electrically biased at a control gate read bias voltage, which turns on or turns off the channel in an overlying active layer 30 based on the amount of trapped electrical charge in a floating gate electrode 54 located between the selected control gate electrode 58 and the overlying active layer 30. All unselected control gate electrodes 58 may be electrically biased at a voltage that turns off the channels in the overlying active layers 30. Generally, the NOR memory array may be operated using electrical biasing schemes known in the art during programming, erasing, and reading operations.

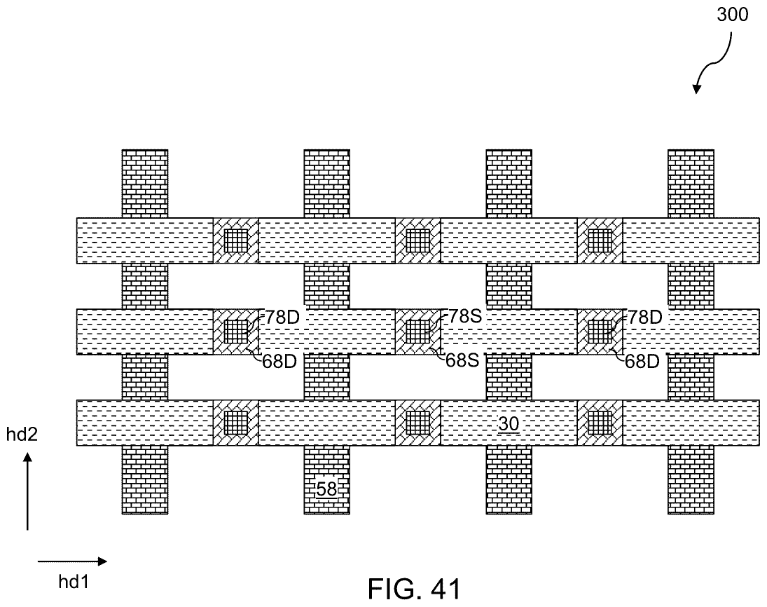

Referring to FIG. 41, selected structural elements within an alternative configuration of the fourth embodiment structure of FIGS. 40A-40C are schematically illustrated. In FIG. 41, the line-level dielectric layer 80, the via-level dielectric layer 70, the contact-level dielectric layer 60, and the dielectric matrix layer 24 are not illustrated. Further, the source lines 88S and the drain lines 88D are not illustrated. Generally, the locations of the source connection via structures 78S and the drain connection via structures 78D may be selected based on the wiring schemes for the source lines 88S and the drain lines 88D. Generally, the source connection via structures 78S and the drain connection via structures 78D may be electrically connected to the source lines 88S and the drain lines 88D to provide a NOR configuration or a NAND configuration for the two-dimensional array 300 of flash memory devices.

Generally, the semiconductor device of the present disclosure may include a first floating gate memory cell which comprises: a composite tunneling dielectric 56 overlying a control gate electrode 58, wherein the composite tunneling dielectric 56 comprises a first dielectric layer 561 and a second dielectric layer 562, wherein the first dielectric layer 561 has a first conduction band offset relative to a Fermi energy of a conductive material in the control gate electrode 58, and the second dielectric layer 562 has a second conduction band offset relative to the Fermi energy of the conductive material, the first conduction band offset being greater than the second conduction band offset; a floating gate electrode 54 overlying the composite tunneling dielectric 56; and a stack of a blocking dielectric 52 and an active layer 30 comprising a semiconductor material and overlying the floating gate electrode 54.

The semiconductor device of the present disclosure may further comprise a second floating gate memory cell, which comprises: an additional composite tunneling dielectric 56 overlying an additional control gate electrode 58; an additional floating gate electrode 54 overlying the additional composite tunneling dielectric 56; and a stack of an additional blocking dielectric 52 and an additional active layer 30 comprising a semiconductor material and overlying the floating gate electrode 54. In one embodiment, the semiconductor device further comprises: a drain contact structure 68D contacting a first top end of the active layer 30 and a first top end of the additional active layer 30; a first source contact structure 68S contacting a second top end of the active layer 30; a second source contact structure 68S contacting a second top end of the additional active layer 30; and a source line 88S electrically connected to the first source contact structure 68S and the second source contact structure 68S.

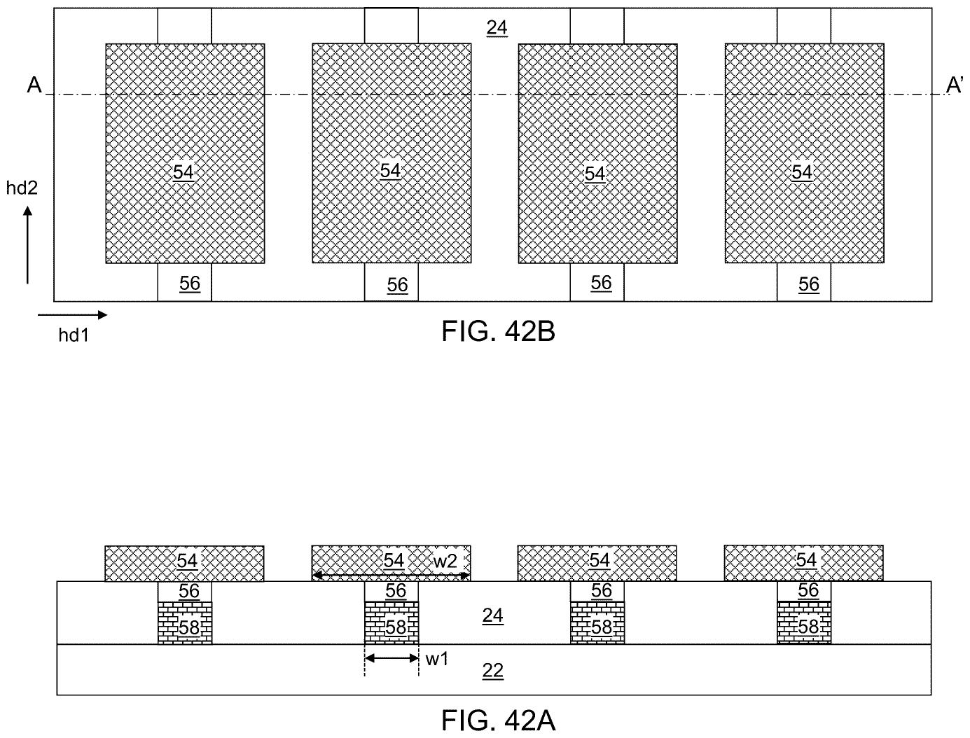

Referring to FIGS. 42A and 42B, a fifth embodiment structure may be derived from the first embodiment structure illustrated in FIGS. 12A and 12B, the second embodiment structure illustrated in FIGS. 24A and 24B, or the third embodiment structure illustrated in FIGS. 31A and 31B by forming a floating gate electrode 54 in lieu of forming a stack of a floating gate electrode 54, a blocking dielectric 52, and an active layer 30. In other words, formation of a blocking dielectric layer 52L or a semiconductor layer 30L is omitted while a floating gate electrode 54 is formed within each area of a unit memory cell.

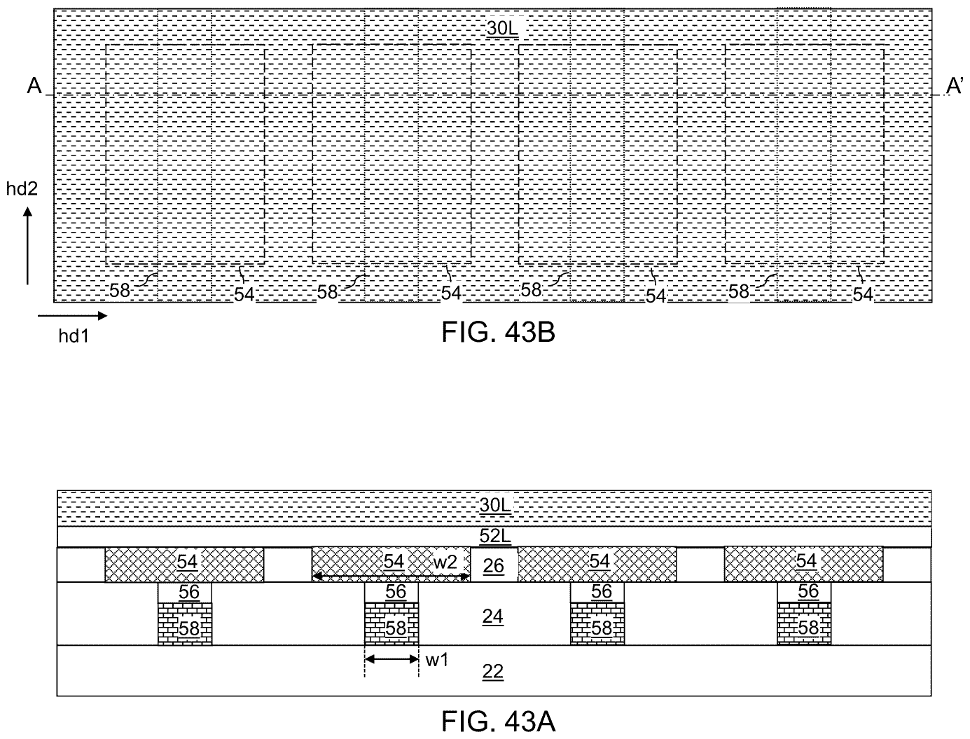

Referring to FIGS. 43A and 43B, a dielectric material such as undoped silicate glass or a doped silicate glass may be deposited and planarized to form a floating-gate-level dielectric layer 26. The top surface of the floating-gate-level dielectric layer 26 may be coplanar with the top surface of the floating gate electrode 54. Subsequently, a blocking dielectric layer 52L and a semiconductor layer 30L may be deposited. The blocking dielectric layer 52L and the semiconductor layer 30L may be the same as described with reference to the first embodiment structure. In the fifth embodiment structure, the blocking dielectric layer 52L is not patterned into an array of blocking dielectrics 52, and the semiconductor layer 30L is not patterned into an array of active layers 30. Instead, each portion of the blocking dielectric layer 52L located within an area of a unit memory cell constitutes a blocking dielectric, and each portion of the semiconductor layer 30L located within an area of a unit memory cell constitutes an active layer. Thus, the blocking dielectrics of a two-dimensional array of flash memory devices are merged into a blocking dielectric layer 52L, and the active layers of the two-dimensional array of flash memory devices are merged into a semiconductor layer 30L in the fifth embodiment structure.

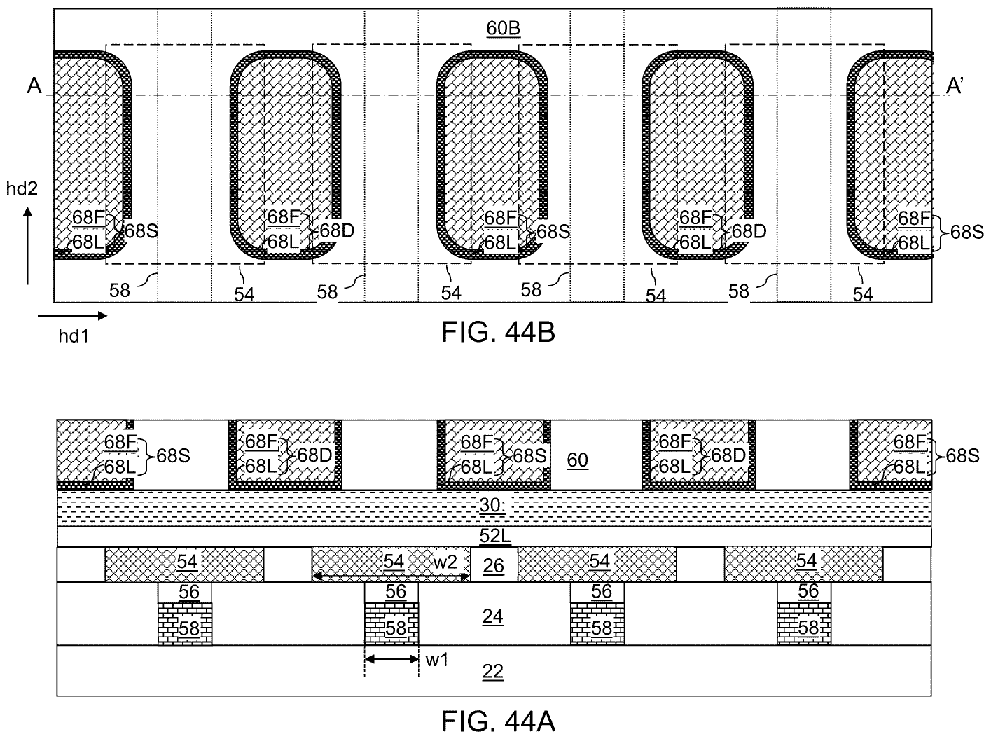

Referring to FIGS. 44A and 44B, the processing steps described with reference to FIGS. 37A-38B may be performed to form a contact-level dielectric layer 60, source contact structures 68S, and drain contact structures 68D.

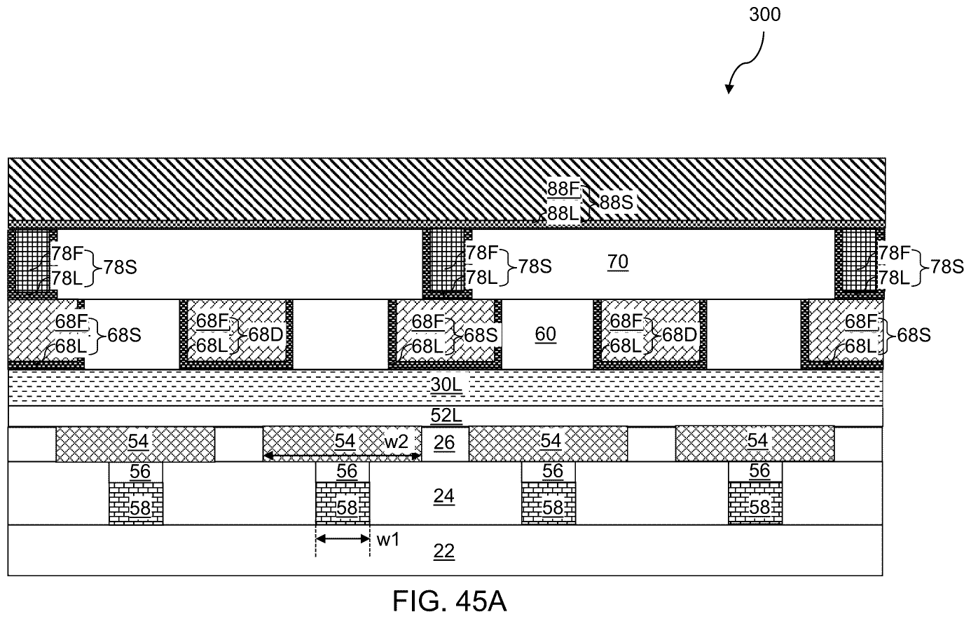

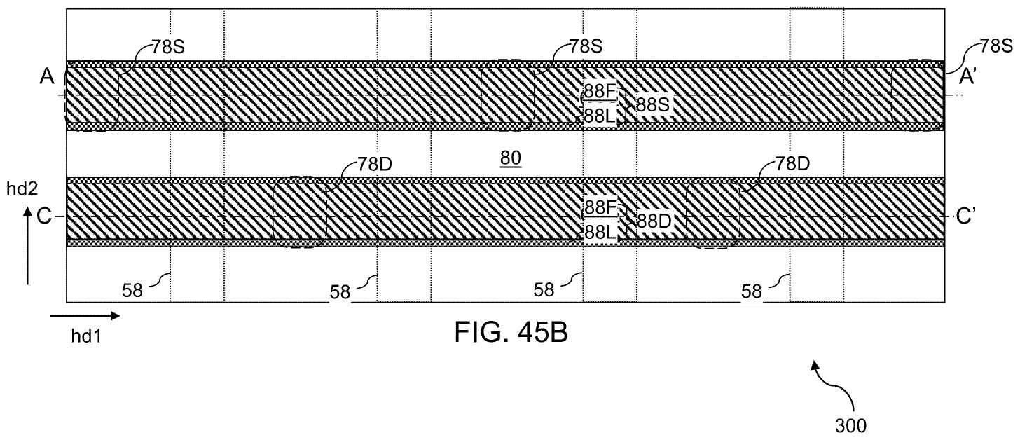

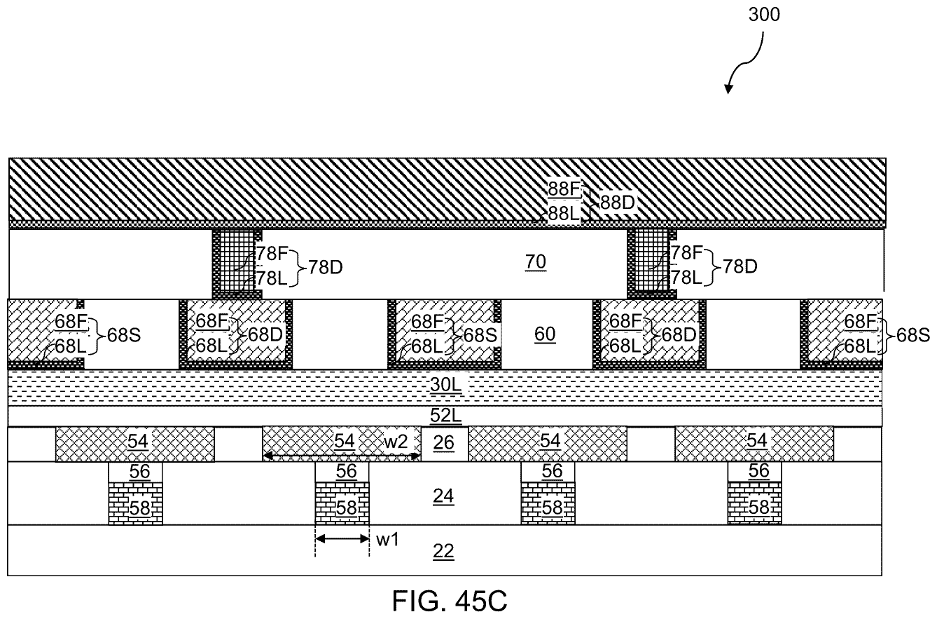

Referring to FIGS. 45A-45C, the processing steps described with reference to FIGS. 39A-39C may be performed to form a via-level dielectric layer 70, source connection via structures 78S, and drain connection via structures 78D. The processing steps described with reference to FIGS. 40A-40C may be performed to form a line-level dielectric layer 80, source lines 88S, and drain lines 88D.

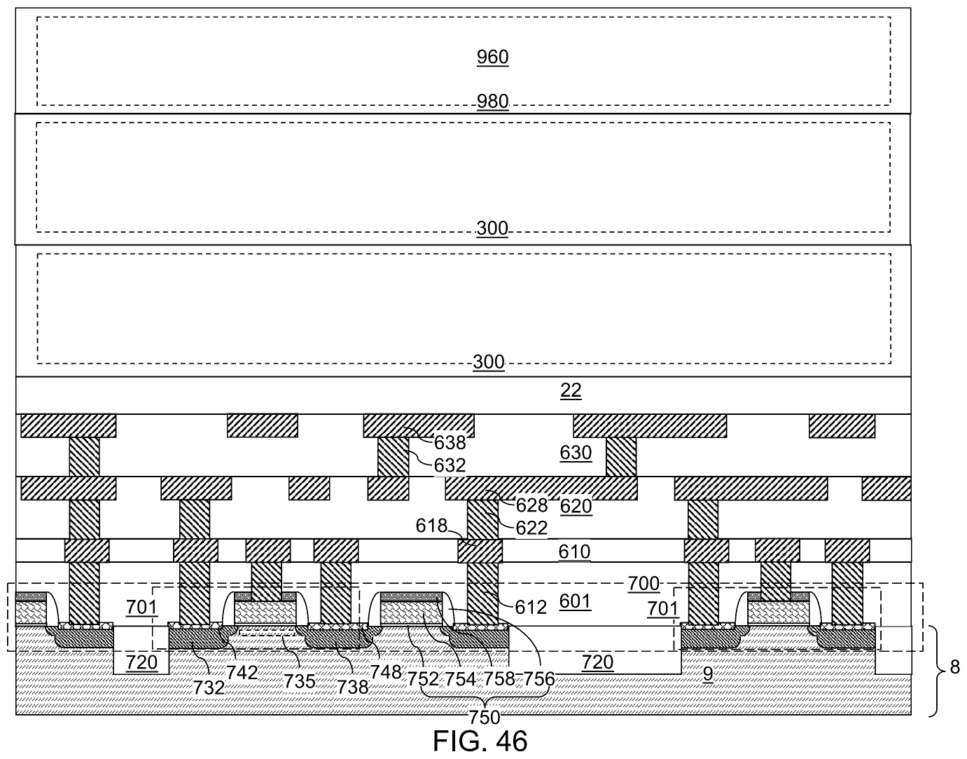

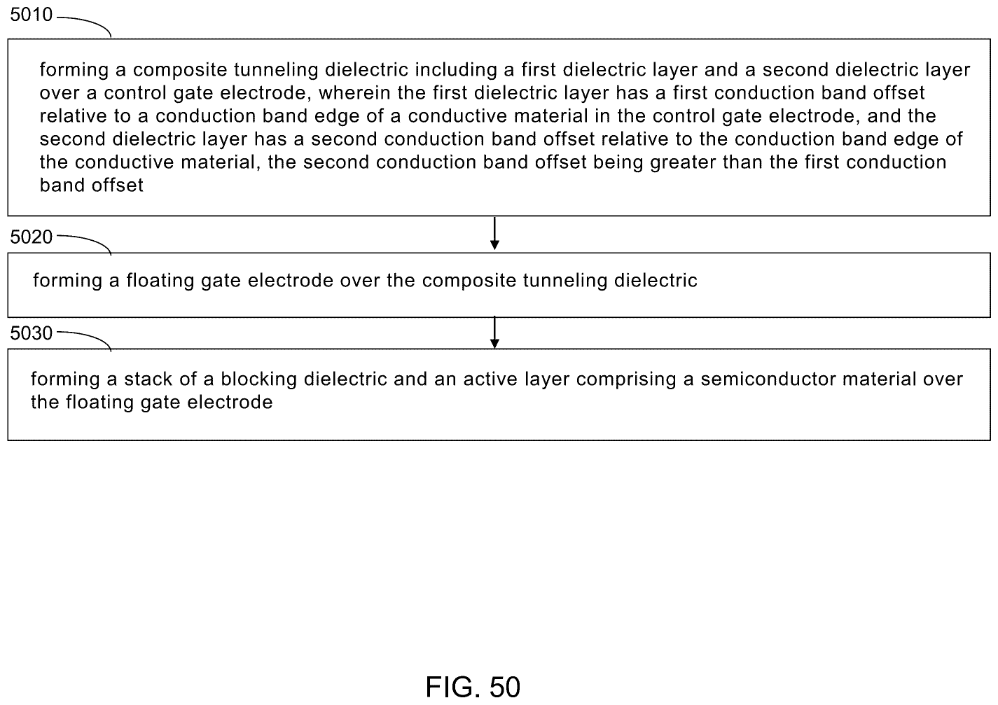

Referring to FIG. 46, an embodiment structure of the present disclosure is illustrated after formation of arrays 300 of flash memory cells, upper-level dielectric material layers 960, and upper-level metal interconnect structures 980. The embodiment structure illustrated in FIG. 50 may be derived from any of the previously described embodiments by forming additional dielectric material layers (which are referred to as the upper-level dielectric material layers 960) and additional metal interconnect structures (which are referred to as upper-level metal interconnect structures 980). Generally, one or more levels of arrays 300 of flash memory cells may be formed. Peripheral circuits for each array 300 of flash memory cells may be provided within the CMOS circuitry 700 located on the semiconductor material layer 9 in the substrate 8.

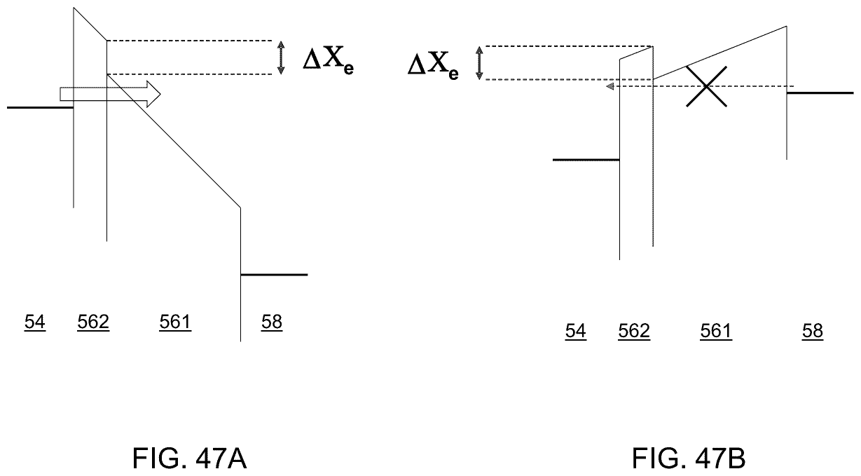

FIG. 47A is a band diagram of a region including a floating gate electrode 54, a composite tunneling dielectric 56, and a control gate electrode 58 during programming of a memory cell of the present disclosure. FIG. 47B is a band diagram of a region including a floating gate electrode 54, a composite tunneling dielectric 56, and a control gate electrode 58 during a hold condition of a memory cell of the present disclosure. Generally, the composite tunneling dielectric 56 of the present disclosure comprises a stack including a first dielectric layer 561 and a second dielectric layer 562. The first dielectric layer 561 has a first conduction band offset relative to a Fermi energy of a conductive material in the control gate electrode 58, and the second dielectric layer 562 has a second conduction band offset relative to the Fermi energy of the conductive material, the first conduction band offset being greater than the second conduction band offset.

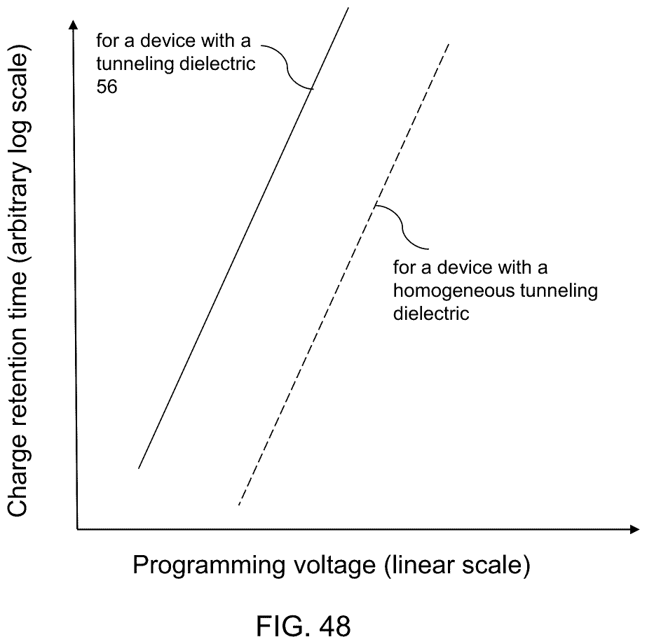

The relative location between the first dielectric layer 561 and the second dielectric layer 562 is selected such that the difference between the first conduction band offset and the second conduction band offset, expressed by the difference in electron affinity ΔXe, provides a narrow energy barrier during a programming operation as illustrated in FIG. 47A, while providing a wider energy barrier during a hold state during which leakage of the electrical charges from the floating gate electrode 54 needs to be suppressed as illustrated in FIG. 47B. With reference to FIG. 48, use of the stack of the first dielectric layer 561 and the second dielectric layer 562 within a composite tunneling dielectric 56 has the net effect of shifting the relationship between required programming voltage and charge retention time such that the programming voltage may be reduced and/or the charge retention time may be increased as illustrated in FIG. 48.

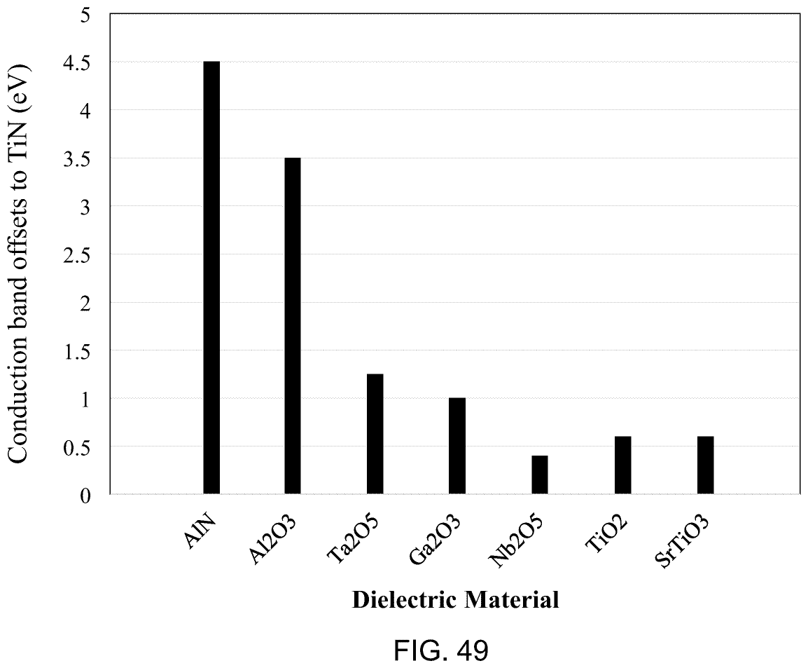

Referring to FIG. 49, a conduction band offset of various exemplary dielectric materials that may be used for the first dielectric layer 561 and the second dielectric layer 562 of the present disclosure is illustrated. In the graph of FIG. 49, all conduction band offsets are measured relative to the Fermi energy in titanium nitride, which is a common material that may be used for a control gate electrode 58. The dielectric materials shown in FIG. 49 are only some examples of materials that may be used for the first dielectric layer 561 and the second dielectric layer 562 of the present disclosure, and as such, are merely illustrative and do not limit the scope of the present disclosure. The mechanism for reducing the programming voltage and suppressing the leakage current as described with reference to FIGS. 47A and 47B is valid even in instance in which any other conductive material is used for the control gate electrode 58.

Referring to FIG. 50, a first flowchart illustrates general processing steps for a method of forming or manufacturing a device structure according to embodiments of the present disclosure.

Referring to step 5010 and FIGS. 1-12B, 20A-24B, 27A-30B, 33A and 33B, 35A and 35B, 36A and 36B, and 42A and 42B, a composite tunneling dielectric 56 comprising a first dielectric layer 561 and a second dielectric layer 562 may be formed over a control gate electrode 58. The first dielectric layer 561 has a first conduction band offset relative to a Fermi energy of a conductive material in the control gate electrode 58, and the second dielectric layer 562 has a second conduction band offset relative to the Fermi energy of the conductive material. The first conduction band offset is greater than the second conduction band offset.

Referring to step 5020 and FIGS. 13A-14B, 25A and 25B, 31A and 31B, 34A and 34B, 35A and 35B, 36A and 36B, and 42A and 42B, a floating gate electrode 54 may be formed over the composite tunneling dielectric 56.

Referring to step 5030 and FIGS. 13A-14B, 25A and 25B, 31A and 31B, 34A and 34B, 35A and 35B, 36A and 36B, and 42A and 42B, a stack of a blocking dielectric 52 and an active layer 30 comprising a semiconductor material may be formed over the floating gate electrode 54.

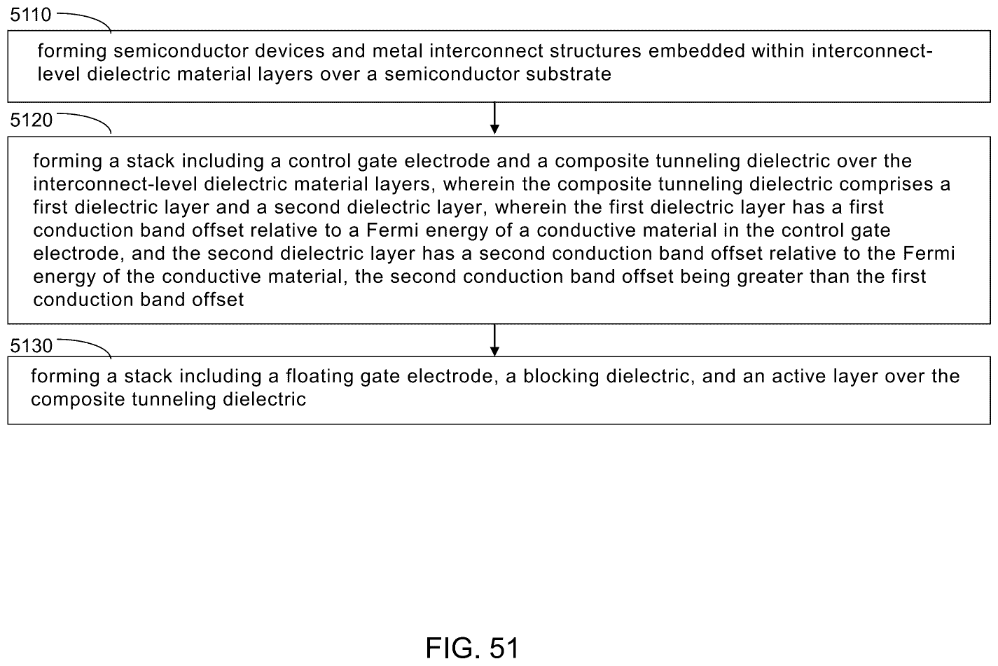

Referring to FIG. 51, a second flowchart illustrates general processing steps for forming or manufacturing a device structure according to embodiments of the present disclosure.

Referring to step 5110 and FIG. 1, semiconductor devices (such as field effect transistors 701) and metal interconnect structures (such as lower interconnect-level metal interconnect structures (612, 618, 622, 628, 631, 638)) embedded within interconnect-level dielectric material layers (such as lower interconnect-level dielectric material layers (601, 610, 620, 630)) may be formed over a semiconductor substrate (such as a substrate 8 including a semiconductor material layer 9).

Referring to step 5120 and FIGS. 1-12B, 20A-24B, 27A-30B, 33A and 33B, 35A and 35B, 36A and 36B, and 42A and 42B, a stack including a control gate electrode 58 and a composite tunneling dielectric 56 may be formed over the interconnect-level dielectric material layers. The composite tunneling dielectric 56 comprises a first dielectric layer 561 and a second dielectric layer 562, wherein the first dielectric layer 561 has a first conduction band offset relative to a Fermi energy of a conductive material in the control gate electrode 58, and the second dielectric layer 562 has a second conduction band offset relative to the Fermi energy of the conductive material. The first conduction band offset is greater than the second conduction band offset.

Referring to step 5130 and FIGS. 13A-14B, 25A and 25B, 31A and 31B, 34A and 34B, 35A and 35B, 36A and 36B, and 42A and 42B, a stack including a floating gate electrode 54, a blocking dielectric 52, and an active layer 30 comprising a semiconductor material may be formed over the composite tunneling dielectric 56.

Referring to all drawings and according to various embodiments of the present disclosure, a semiconductor device comprising a first floating gate memory cell is provided. The first floating gate memory cell comprises: a composite tunneling dielectric 56 overlying a control gate electrode 58, wherein the composite tunneling dielectric 56 comprises a first dielectric layer 561 and a second dielectric layer 562, wherein the first dielectric layer 561 has a first conduction band offset relative to a Fermi energy of a conductive material in the control gate electrode 58, and the second dielectric layer 562 has a second conduction band offset relative to the Fermi energy of the conductive material, the first conduction band offset being greater than the second conduction band offset; a floating gate electrode 54 overlying the composite tunneling dielectric 56; and a stack of a blocking dielectric 52 and an active layer 30 comprising a semiconductor material and overlying the floating gate electrode 54.

In one embodiment, the semiconductor device comprises a dielectric matrix layer 24 laterally surrounding the control gate electrode 58 and the composite tunneling dielectric 56, wherein a top surface of the dielectric matrix layer 24 is coplanar with a top surface of the composite tunneling dielectric 56. In one embodiment, the semiconductor device comprises: a contact-level dielectric layer 60 overlying the floating gate electrode 54, the blocking dielectric 52, and the active layer 30; a source contact structure 68S vertically extending through the contact-level dielectric layer 60 and contacting a first top end of the active layer 30; and a drain contact structure 68D vertically extending through the contact-level dielectric layer 60 and contacting a second top end of the active layer 30.

In one embodiment, the composite tunneling dielectric 56 has a first width along a first horizontal direction hd1; and the floating gate electrode 54 has a second width w2 along the first horizontal direction hd1 which is greater than the first width w1. In one embodiment, the first dielectric layer 561 contacts the control gate electrode 58; and the second dielectric layer 562 contacts the floating gate electrode 54. In one embodiment, the first dielectric layer 561 contacts the floating gate electrode 54; and the second dielectric layer 562 contacts the control gate electrode 58.

In one embodiment, the first dielectric layer 561 comprises a material selected from AlN and Al₂O₃; and the second dielectric layer 562 comprises a material selected from Ta₂O₅, Ga₂O₃, Nb₂O₅, TiO₂, and SiTiO₃.

In one embodiment, the semiconductor device further comprises a second floating gate memory cell which comprises: an additional composite tunneling dielectric 56 overlying an additional control gate electrode 58; an additional floating gate electrode 54 overlying the additional composite tunneling dielectric 56; and a stack of an additional blocking dielectric 52 and an additional active layer 30 comprising a semiconductor material and overlying the floating gate electrode 54. In one embodiment, the semiconductor device further comprises: a drain contact structure 68D contacting a first top end of the active layer 30 and a first top end of the additional active layer 30; a first source contact structure 68S contacting a second top end of the active layer 30; a second source contact structure 68S contacting a second top end of the additional active layer 30; and a source line electrically connected to the first source contact structure 68S and the second source contact structure 68S.

Embodiments of the present disclosure provide novel inverted flash memory cell designs. Electron tunneling in the flash memory cell of the present disclosure occurs between the floating gate electrode 54 and the control gate electrode 58. The backside tunneling configuration facilitates reversal of the memory state of the floating gate electrode 54 during programming and erase operations, while increasing the charge retention time for the floating gate electrodes 54.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a composite tunneling dielectric comprising a first dielectric layer and a second dielectric layer over a control gate electrode, wherein the first dielectric layer has a first conduction band offset relative to a Fermi energy of a conductive material in the control gate electrode, and the second dielectric layer has a second conduction band offset relative to the Fermi energy of the conductive material, the first conduction band offset being greater than the second conduction band offset;
forming a floating gate electrode over the composite tunneling dielectric; and
forming a stack of a blocking dielectric and an active layer comprising a semiconductor material over the floating gate electrode.

2. The method of claim 1, wherein the composite tunneling dielectric and the control gate electrode are formed by:
depositing a control gate electrode material layer and a composite tunneling dielectric layer over an insulating layer; and
patterning the composite tunneling dielectric layer and the control gate electrode material layer, wherein a remaining portion of the control gate electrode material layer comprises the control gate electrode, and a remaining portion of the composite tunneling dielectric layer comprises the composite tunneling dielectric.

3. The method of claim 1, further comprising forming a dielectric matrix layer around the control gate electrode and the composite tunneling dielectric, wherein a top surface of the dielectric matrix layer 24 is coplanar with a top surface of the composite tunneling dielectric.

4. The method of claim 3, further comprising:
forming a contact-level dielectric layer around the floating gate electrode, the blocking dielectric, and the active layer;
forming a source contact structure through the contact-level dielectric layer on a first top end of the active layer; and
forming a drain contact structure through the contact-level dielectric layer on a second top end of the active layer.

5. The method of claim 1, wherein the floating gate electrode is formed by depositing a floating gate electrode material layer over the composite tunneling dielectric, and by patterning the floating gate electrode material layer.

6. The method of claim 5, wherein:
the composite tunneling dielectric has a first width along a first horizontal direction; and
the floating gate electrode is formed with a second width along the first horizontal direction, wherein the second width is greater than the first width.

7. The method of claim 5, further comprising:
depositing a blocking dielectric layer and a semiconductor layer over the floating gate electrode material layer;
forming an etch mask over the semiconductor layer; and
performing an anisotropic etch process that etches portions of the semiconductor layer, the blocking dielectric layer, and the floating gate electrode material layer that are not masked by the etch mask, wherein:
a patterned portion of the semiconductor layer comprises the active layer;
a patterned portion of the blocking dielectric layer comprises the blocking dielectric; and
a patterned portion of the floating gate electrode material layer comprises the floating gate electrode.

8. The method of claim 1, wherein the first conduction band offset is greater than the second conduction band offset by at least 2.00 eV.

9. The method of claim 1, wherein:
the first dielectric layer comprises a material selected from AlN and Al₂O₃; and
the second dielectric layer comprises a material selected from Ta₂O₅, Ga₂O₃, Nb₂O₅, TiO₂, and SiTiO₃.

10. A method of forming a device structure, comprising:
forming semiconductor devices and metal interconnect structures embedded within interconnect-level dielectric material layers over a semiconductor substrate;
forming a stack including a control gate electrode and a composite tunneling dielectric over the interconnect-level dielectric material layers, wherein the composite tunneling dielectric comprises a first dielectric layer and a second dielectric layer, wherein the first dielectric layer has a first conduction band offset relative to a Fermi energy of a conductive material in the control gate electrode, and the second dielectric layer has a second conduction band offset relative to the Fermi energy of the conductive material, the first conduction band offset being greater than the second conduction band offset; and
forming a stack including a floating gate electrode, a blocking dielectric, and an active layer comprising a semiconductor material over the composite tunneling dielectric.

11. The method of claim 10, further comprising:
depositing a dielectric matrix layer around, and over, the control gate electrode and the composite tunneling dielectric; and
planarizing the dielectric matrix layer by removing portions of the dielectric matrix layer from above a horizontal plane including a top surface of the composite tunneling dielectric.

12. The method of claim 10, further comprising:
depositing a layer stack including a floating gate electrode material layer, a blocking dielectric layer, and a semiconductor layer over the composite tunneling dielectric;
forming an etch mask over the layer stack; and
patterning the layer stack by performing an anisotropic etch process that removes portions of the layer stack that are not masked by the etch mask, wherein:
a patterned portion of the semiconductor layer comprises the active layer;
a patterned portion of the blocking dielectric layer comprises the blocking dielectric; and
a patterned portion of the floating gate electrode material layer comprises the floating gate electrode.

13. A semiconductor device comprising a first floating gate memory cell, wherein the first floating gate memory cell comprises:
a composite tunneling dielectric overlying a control gate electrode, wherein the composite tunneling dielectric comprises a first dielectric layer and a second dielectric layer, wherein the first dielectric layer has a first conduction band offset relative to a Fermi energy of a conductive material in the control gate electrode, and the second dielectric layer has a second conduction band offset relative to the Fermi energy of the conductive material, the first conduction band offset being greater than the second conduction band offset;
a floating gate electrode overlying the composite tunneling dielectric; and
a stack of a blocking dielectric and an active layer comprising a semiconductor material and overlying the floating gate electrode.

14. The semiconductor device of claim 13, further comprising a dielectric matrix layer laterally surrounding the control gate electrode and the composite tunneling dielectric, wherein a top surface of the dielectric matrix layer 24 is coplanar with a top surface of the composite tunneling dielectric.

15. The semiconductor device of claim 13, further comprising:
a contact-level dielectric layer overlying the floating gate electrode, the blocking dielectric, and the active layer;
a source contact structure vertically extending through the contact-level dielectric layer and contacting a first top end of the active layer; and
a drain contact structure vertically extending through the contact-level dielectric layer and contacting a second top end of the active layer.

16. The semiconductor device of claim 13, wherein:
the composite tunneling dielectric has a first width along a first horizontal direction; and
the floating gate electrode has a second width along the first horizontal direction which is greater than the first width.

17. The semiconductor device of claim 13, wherein:
the first dielectric layer contacts the control gate electrode; and
the second dielectric layer contacts the floating gate electrode.

18. The semiconductor device of claim 13, wherein:
the first dielectric layer contacts the floating gate electrode; and
the second dielectric layer contacts the control gate electrode.

19. The semiconductor device of claim 13, wherein:
the first dielectric layer comprises a material selected from AlN and Al₂O₃; and
the second dielectric layer comprises a material selected from Ta₂O₅, Ga₂O₃, Nb₂O₅, TiO₂, and SiTiO₃.

20. The semiconductor device of claim 13, further comprising a second floating gate memory cell which comprises:
an additional composite tunneling dielectric overlying an additional control gate electrode;
an additional floating gate electrode overlying the additional composite tunneling dielectric; and
a stack of an additional blocking dielectric and an additional active layer comprising a semiconductor material and overlying the floating gate electrode,
wherein the semiconductor device further comprises:
a drain contact structure contacting a first top end of the active layer and a first top end of the additional active layer;
a first source contact structure contacting a second top end of the active layer;
a second source contact structure contacting a second top end of the additional active layer; and
a source line electrically connected to the first source contact structure and the second source contact structure.
